(19) United States
(12) Patent Application Publication
(10) Pub. No.: US 2025/0248114 A1
(43) Pub. Date: Jul. 31, 2025

(54) STACKED TRANSISTOR FRONTSIDE CONTACT FORMATION

(71) Applicant: INTERNATIONAL BUSINESS MACHINES CORPORATION, ARMONK, NY (US)

(72) Inventors: Abir Shadman, Albany, NY (US); Chen Zhang, Santa Clara, CA (US); Jay William Strane, Wappingers Falls, NY (US); Junli Wang, Slingerlands, NY (US)

(21) Appl. No.: 18/425,468

(22) Filed: Jan. 29, 2024

(51) Int. Cl. H01L 27/088; H01L 29/417; H01L 29/423; H01L 29/66; H01L 29/775; H01L 29/786

(52) U.S. Cl. CPC H10D 84/83; H10D 30/014; H10D 30/43; H10D 30/6735; H10D 30/6757; H10D 64/251

(57) ABSTRACT

A semiconductor IC structure includes an upper transistor and lower transistor each with respective source/drain (S/D) regions. The upper S/D region includes a S/D cut sidewall. A first frontside contact is in contact with the upper S/D region and includes a first conductive portion with a first cut sidewall that is substantially coplanar with the S/D cut sidewall. A second frontside contact is in contact with the lower S/D region and includes a second conductive portion with a second cut sidewall. A contact cut region may be between the first and second frontside contacts. This structure may be fabricated at least in part by forming a monolithic frontside contact against the lower S/D region and against the upper S/D region and simultaneously separating the monolithic frontside contact into the first frontside contact and the second frontside contact while removing a portion of the upper S/D region.

### BACKGROUND

The embodiments of the present disclosure relate to fabrication methods and resulting structures for semiconductor integrated circuit (IC) devices. The fabrication of frontside contacts within stacked transistors is challenging due to space constraints in locating an upper transistor contact and a lower transistor contact. The relatively tight spacing between the upper transistor frontside contact and the lower transistor frontside contact typically increases the propensity of electrical shorting between the upper transistor frontside contact and the lower transistor frontside contact and/or increases the propensity of electrical shorting between the lower transistor frontside contact and the upper transistor.

### SUMMARY

In an embodiment of the disclosure, a semiconductor integrated circuit (IC) device is presented. The semiconductor IC device includes an upper transistor with an upper source/drain (S/D) region that has a S/D cut sidewall and a lower transistor with a lower S/D region. The semiconductor IC device further includes a first frontside contact in contact with the upper S/D region. The first frontside contact includes a first conductive portion with a first cut sidewall that is substantially coplanar with the S/D cut sidewall. The semiconductor IC device further includes a second frontside contact in contact with the lower S/D region. The second frontside contact includes a second conductive portion with a second cut sidewall that faces the S/D cut sidewall and the first cut sidewall.

In an embodiment of the disclosure, another semiconductor IC device is presented. This semiconductor integrated circuit (IC) device includes an upper transistor and a lower transistor. The semiconductor integrated circuit (IC) device further includes a first frontside contact and a second frontside contact. The first frontside contact includes a first conductive portion that has a first cut sidewall and that has a first opposing sidewall that faces away from the first cut sidewall. The first frontside contact further includes a first liner between the first conductive portion and the upper transistor. The second frontside contact includes a second conductive portion that has a second cut sidewall that faces the first cut sidewall and that has a second opposing sidewall that faces away from the second cut sidewall. The second frontside contact further includes a second liner between the second conductive portion and the lower transistor. The semiconductor integrated circuit (IC) device further includes a contact cut region between the first frontside contact and the second frontside contact that includes a first interlayer dielectric (ILD) directly upon the first cut sidewall and directly upon the second cut sidewall.

In an embodiment of the disclosure, a method of fabricating a semiconductor integrated circuit (IC) device is presented. The method includes forming a monolithic frontside contact against a lower source/drain (S/D) region and against an upper S/D region and simultaneously separating the monolithic frontside contact into a first frontside contact and a second frontside contact and removing a portion of the upper S/D region.

The above summary is not intended to describe each illustrated embodiment or every implementation or example of the present disclosure.

### BRIEF DESCRIPTION OF THE DRAWINGS

The drawings included in the disclosure are incorporated into, and form part of, the specification. They illustrate embodiments of the present disclosure and, along with the description, explain the principles of the disclosure. The drawings are only illustrative of certain embodiments and do not limit the disclosure.

FIG. 1 depicts a cross-section view of a semiconductor IC device that includes a stacked transistor with frontside contacts, according to one or more embodiments of the disclosure.

FIG. 2 depicts a partial top-down structure view of an illustrative semiconductor IC device and establishes a cross-sectional plane for the fabrication views of the semiconductor IC device depicted in FIG. 3 through FIG. 9, according to one or more embodiments of the disclosure.

FIG. 3 through FIG. 9 depict various fabrication structure cross-section views of an illustrative semiconductor IC device that includes a stacked transistor with frontside contacts, according to one or more embodiments of the disclosure.

FIG. 10 depicts a method of fabricating a semiconductor IC device that includes a stacked transistor with frontside contacts, according to one or more embodiments of the disclosure.

### DETAILED DESCRIPTION

The present disclosure relates to fabrication methods and resulting semiconductor integrated circuit (IC) devices that include stacked transistor with respective frontside contacts that are electrically connected to respective regions, such as respective source/drain (S/D) regions of the stacked transistor. Due to the desire for continued stacked transistor scaling, overlap between the upper transistor and the lower transistor (e.g., the degree to which the respective active region perimeters of the upper transistor and the lower transistor are horizontally offset) continues to shrink. This smaller overlap increases space constraints in locating the frontside contacts and typically increases the propensity of electrical shorting therebetween and/or increases the propensity of electrical shorting between the upper transistor and the frontside contact that is associated with the lower transistor.

The embodiments of the present disclosure recognize the potential benefits of semiconductor IC device fabrication techniques that allow for a frontside contacts to connect against respective transistor regions of a stacked transistor. To achieve these and potential other benefits, semiconductor IC device(s) are presented that respectively include a stacked transistor with an upper transistor stacked vertically over a lower transistor.

A transistor is a type of microdevice that may be fabricated in semiconductor IC device front-end-of-line (FEOL) fabrication operations. Conventional transistors, or the like, incorporate planar field effect transistors (FETs) in which current flows through a semiconducting channel between a source and a drain, in response to a voltage applied to a control gate. The semiconductor industry strives to obey Moore's law, which holds that each successive generation of integrated circuit devices shrinks to half its size and operates twice as fast. As device dimensions have shrunk, however, conventional silicon device geometries and materials have had trouble maintaining switching speeds without incurring failures such as, for example, leaking current from the device into the semiconductor substrate. Several new technologies emerged that allowed chip designers to continue shrinking transistor sizes. A FET generally is a transistor in which output current, i.e., source-drain current, is controlled by a voltage applied to an associated gate. A FET typically has three terminals, i.e., a gate structure, a source region, and a drain region. A gate structure may be a structure used to control output current (i.e., flow of carriers in the channel) of a semiconducting device through electrical or magnetic fields. A channel may be the region of the FET underlying the gate structure and between the source and drain of the semiconductor IC device that becomes conductive when the semiconductor device is turned on. The source is a doped region in the semiconductor IC device, in which majority carriers are flowing into the channel. A drain is a doped region in the semiconductor IC device located at the end of the channel, in which carriers are flowing out of the transistor through the drain.

One technology change modified the structure of the FET from a planar device to a three-dimensional device in which the semiconducting channel was replaced by a fin that extends out from the plane of the substrate. In such a device, commonly referred to as a FinFET, the control gate wraps around three sides of the fin to influence current flow from three surfaces instead of one. The improved control achieved with a 3D design results in faster switching performance and reduced current leakage. Building taller devices has also permitted increasing the device density within the same footprint that had previously been occupied by a planar FET.

The FinFET concept was further extended by developing a gate all-around FET, or GAA FET, in which the gate fully wraps around one or more channels for maximum control of the current flow therein. In the GAA FET, the channels can take the form of nanolayers, nanosheets, or the like, that are isolated from the substrate. In the GAA FET, channel surfaces are in respective contact with the source and drain and other respective channel surfaces are in contact with and surrounded by the gate.

The flowcharts and cross-sectional diagrams in the drawings illustrate a method of fabricating semiconductor IC device, such as a processor, FPGA, memory module, or the like. In some alternative implementations, the fabrication steps may occur in a different order than that which is noted in the drawings, and certain additional fabrication steps may be implemented between the steps noted in the drawings. Moreover, any of the layered structures depicted in the drawings may contain multiple sublayers.

Various embodiments of the present disclosure are described herein with reference to the related drawings. Alternative embodiments can be devised without departing from the scope of the present disclosure. It is noted that various connections and positional relationships (e.g., over, below, adjacent, etc.) are set forth between elements in the following description and in the drawings. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” if the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

For purposes of the description hereinafter, the terms “upper,” “lower,” “right,” “left,” “vertical,” “horizontal,” “top,” “bottom,” and derivatives thereof shall relate to the depicted structure(s) as oriented. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements.

The terms “about,” “substantially,” “approximately,” and variations thereof, are intended to include the degree of error associated with measurement of the particular quantity based upon the equipment available at the time of filing the application. For example, substantial coplanarity between various materials can include an appropriate manufacturing tolerance of ±8%, ±5%, ±2%, or the like, difference between the coplanar materials.

As used herein, the term “coplanar” refers to two surfaces that lie in a common plane. In other words, two surfaces are coplanar if there exists a geometric plane that contains the points of both of the surfaces. Accordingly, two surfaces may be referred to as substantially coplanar despite deviations from coplanarity, so long as those deviations do not impact the desired result of the coplanarity.

As used herein, the terms “selective” or “selectively” in reference to a material removal or etch process denote that the rate of material removal for a first material is greater than the rate of removal for at least another material of the structure to which the material removal process is applied. For example, in certain embodiments, a selective etch may include an etch chemistry that removes a first material selectively to a second material by a ratio of 2:1 or greater, e.g., 5:1, 10:1 or 20:1.

For the sake of brevity, conventional techniques related to semiconductor IC device fabrication may or may not be described in detail herein. Moreover, the various tasks and process steps described herein can be incorporated into a more comprehensive procedure or process having additional steps or functionality not described in detail herein. Various steps in the manufacture of semiconductor devices are well known and so, in the interest of brevity, many conventional steps will only be mentioned briefly herein or will be omitted entirely without providing the well-known process details.

In general, the various processes used to form a semiconductor IC device that may be packaged into an IC package fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photoresist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

Turning now to an overview of technologies that are more specifically relevant to aspects of the present disclosure, a metal-oxide-semiconductor field-effect transistor (MOSFET) may be used for amplifying or switching electronic signals. The MOSFET has a source electrode, a drain electrode, and a metal oxide gate electrode. The metal gate portion of the metal oxide gate electrode may be electrically insulated from the main semiconductor n-channel or p-channel by a thin layer of insulating material, for example, silicon dioxide or glass, which makes the input resistance of the MOSFET relatively high. The gate voltage controls whether the current path from the source to the drain may be an open circuit (“off”) or a resistive path (“on”). N-type field effect transistors (nFET) and p-type field effect transistors (pFET) are two types of complementary MOSFETs. The nFET includes n-doped source and drain junctions and uses electrons as the current carriers. The pFET includes p-doped source and drain junctions and uses holes as the current carriers. Complementary metal oxide semiconductor (CMOS) is a technology that uses complementary and symmetrical pairs of p-type and n-type MOSFETs to implement logic functions. As mentioned above, hole mobility on the pFET may have an impact on overall device performance.

The wafer footprint of a FET may be related to the electrical conductivity of the channel material. If the channel material has a relatively high conductivity, the FET can be made with a correspondingly smaller wafer footprint. A method of increasing channel conductivity and decreasing FET size is to form the channel as a nanostructure, such as a nano wire, nano ribbon, nanolayer, nanosheet, or the like, hereinafter referred to as a nanolayer. For example, a GAA FET provides a relatively small FET footprint by forming the channel region as a series of vertically stacked nanolayers. In a GAA configuration, a GAA FET includes a source region, a drain region and vertically stacked nanolayer channels between the source and drain regions. These devices typically include one or more suspended nanolayers that serve as the channel. A gate surrounds the stacked nanolayers and regulates electron flow through the nanolayers between the source and drain regions. GAA FETs may be fabricated by forming alternating layers of active nanolayers and sacrificial nanolayers. The sacrificial nanolayers are released from the active nanolayers before the FET device may be finalized. For n-type FETs, the active nanolayers are typically silicon (Si) and the sacrificial nanolayers are typically silicon germanium (SiGe). For p-type FETs, the active nanolayers can be SiGe and the sacrificial nanolayers can be Si. In some implementations, the active nanolayers of a p-type FET can be SiGe or Si, and the sacrificial nanolayers can be Si or SiGe. Forming the nanolayers from alternating layers of active nanolayers formed from a first type of semiconductor material (e.g., Si for n-type FETs, and SiGe for p-type FETs) and sacrificial nanolayers formed from a second type of semiconductor material (e.g., SiGe for n-type FETs, and Si for p-type FETs) may provide for superior channel electrostatics control, which may be necessary for continuously scaling gate lengths.

For some transistors, integration of the transistors with a frontside back-end-of-line (BEOL) network is one of the key challenges to providing increasing packaged IC device densities and performance increases without a resulting increase in a likelihood of shorting therebetween.

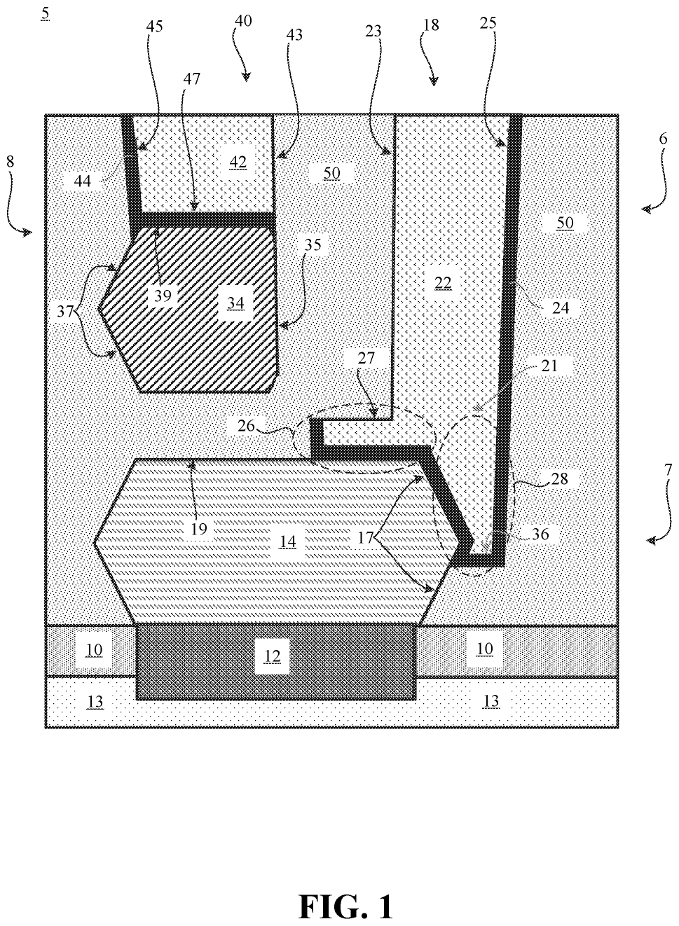

Referring now to FIG. 1, a cross-section view of a semiconductor IC device 5 that includes a stacked transistor 6 that includes a lower transistor 7 and upper transistor 8 is depicted. The lower transistor 7 may include respective lower source/drain (S/D) regions 14. The upper transistor 8 may include respective upper lower source/drain (S/D) regions 34. For clarity, one lower S/D region 14 and one upper S/D region 34 are depicted in this cross-section and the other of the lower S/D region 14 and the other upper S/D region 34 may lay in a cross section that exists into or out of the page. The upper transistor 8 may include an active region that overlaps with an active region of the lower transistor 7. For example, upper S/D region 34 may be inset with respect to lower S/D region 14.

One or more respective lower channels (not shown) may connect the lower S/D regions 14 and one or more respective upper channels (not shown) may connect the upper S/D regions 34. One or more conductive gate(s) may be against the one or more respective lower channels and/or the one or more respective upper channels. The one or more conductive gate(s) may be adequately electrically isolated from the lower S/D region 14 and the upper S/D region 34.

The semiconductor IC device 5 further includes a first frontside contact 40 in contact with the upper S/D region 34. The first frontside contact 40 includes a first conductive portion 42 with a first cut sidewall 43 that may be substantially coplanar with a S/D cut sidewall 35 of the upper S/D region 34.

The S/D cut sidewall 35 may be distal or otherwise opposing to one or more (111) crystallographic plane side surfaces 37 of the upper S/D region 34. The S/D cut sidewall 35 may be formed by removing one or more (111) crystallographic plane side surfaces the upper S/D region 34 simultaneously with separating a monolithic frontside contact into the first frontside contact 40 and a second frontside contact 18.

The second frontside contact 18 may be in contact with the lower S/D region 14. The second frontside contact 18 includes a second conductive portion 22 with a second cut sidewall 23 that faces the S/D cut sidewall 35 and the first cut sidewall 43.

In an example, the S/D cut sidewall 35, the first cut sidewall 43, and the second cut sidewall 23 are substantially vertical. This may result when utilizing a highly directional vertical etch (such as an ion etch) in the associated fabrication stages to form the semiconductor IC device 5.

In an example, one or more interlayer dielectric(s) (ILD) 50 may be directly against the S/D cut sidewall 35, the first cut sidewall 43, and the second cut sidewall 23. In another example, the ILD(s) 50 may be further directly against the upper S/D region 34, the lower S/D region 14, the first frontside contact 40, and the second frontside contact 18.

In an example, the first conductive portion 42 further comprises a first opposing sidewall 45 that faces away from the second frontside contact 18, and the second conductive portion 22 further comprises a second opposing sidewall 25 that faces away from the first frontside contact 40.

In an example, the semiconductor IC device 5, further includes a first liner 44 between the first opposing sidewall 45 and the ILD(s) 50 and between the first conductive portion 42 and the upper S/D region 34. That is, the liner 44 may exist on the surfaces of the first frontside contact 40 except for the S/D cut sidewall 35. In an example, the first liner 44 may be between a bottom surface 47 of the first conductive portion 42 and a (100) crystallographic plane top surface 39 of the upper S/D region 14.

In an example, the semiconductor IC device 5, further includes a second liner 24 between the second opposing sidewall 25 and the ILD(s) 50 and between the second conductive portion 22 and the lower S/D region 14. That is, the liner 24 may exist on the surfaces of the second frontside contact 18 except for the second cut sidewall 23 and a third cut sidewall 27. In an example, the second liner 24 may further be between a bottom surface 36 of the second conductive portion 22 and the ILD(s) 50.

In an example, the second liner 24 may be directly against a (100) crystallographic plane top surface 19 of the lower S/D region 14. In an example, the second liner 24 may be directly against one or more (111) crystallographic plane side surfaces 17 of the lower S/D region 14. This may result due to the second frontside contact 18 including a wraparound portion 21 that includes at least a portion 26 that contacts against the (100) crystallographic plane top surface 19 and that includes at least a portion 28 that contacts against the one or more (111) crystallographic plane side surfaces 17 of the lower S/D region 14.

In an example, the third cut sidewall 27 may be vertically between a bottom surface of the upper S/D region 34 and the (100) crystallographic plane top surface 19 of the lower S/D region 14. This may result because of the existence of the portion 26 in the second frontside contact 18. In an example, the ILD(s) 50 may be further directly against the third cut sidewall 27. In other words, the liner 24 is not present or otherwise between the third cut sidewall 27 and the ILD 50. Rather, the ILD(s) 50 may be directly against the third cut sidewall 27.

In an example, the semiconductor IC device 5 further includes a backside contact placeholder 12 under the lower S/D region 14 between shallow trench isolation (STI) regions 10. In an example, the semiconductor IC device 5, further includes a backside structure 13 such as a backside ILD, substrate structure, or the like. In some examples, the semiconductor IC device 5 further includes a frontside back end of line (BEOL) network (not shown) that may be connected to the first frontside contact 40 and to the second frontside contact 18. In some examples, the semiconductor IC device 5 further includes a backside BEOL network (not shown) that may be connected to the backside structure 13.

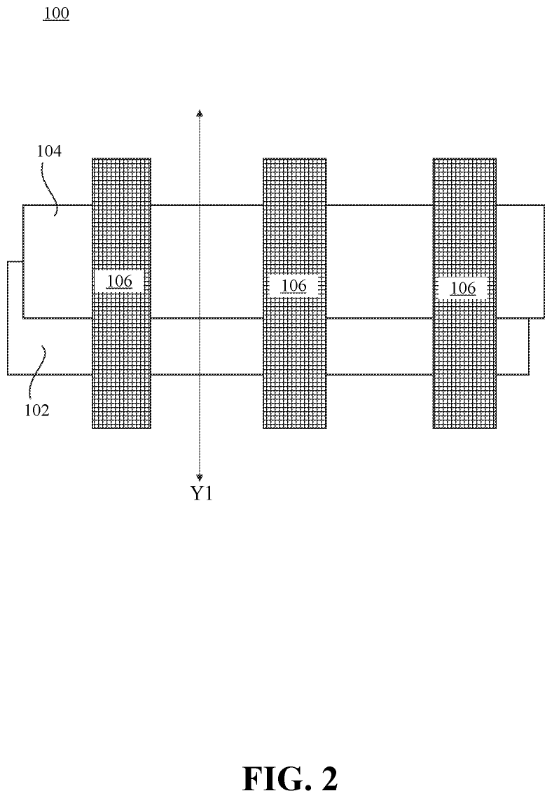

FIG. 2 depicts a partial top-down structure view of a semiconductor IC device 100 and establishes an illustrative cross-sectional plane Y1 for the views of the semiconductor IC device structures of the disclosure. The illustrated semiconductor IC device 100 includes an upper transistor active region 104 and a lower transistor active region 102. As depicted, the upper transistor active region 104 overlaps with the lower transistor active region 102. Upper S/D region(s) of the upper transistor may be formed within the upper transistor active region 104 between gate structures 106. Similarly, lower S/D region(s) of the lower transistor may be formed within the lower transistor active region 102 between gate structures 106. FIG. 2 defines a plane Y1 across the lower transistor active region 102 and across the upper transistor active region 104 in between adjacent gate structure 106. The plane Y1 is an illustrative plane of the cross-sectional views of the semiconductor IC device 100 of the description of the embodiments.

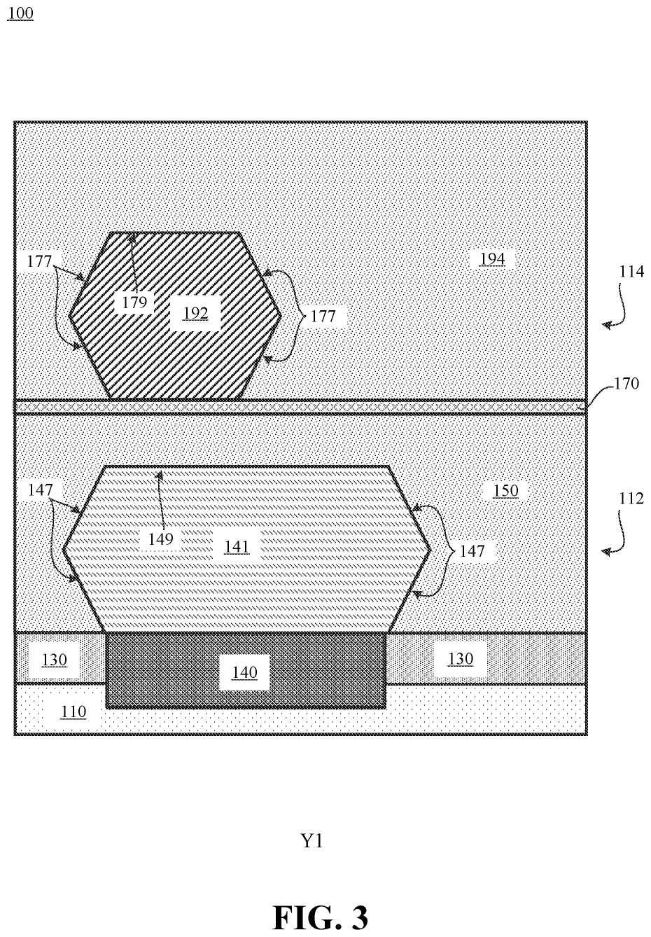

FIG. 3 depicts a cross-sectional view of a semiconductor IC device 100 that includes a stacked transistor of a lower transistor 112 and an upper transistor 114 that is to eventually include respective frontside contacts to respective source/drain regions of the stacked transistor. For clarity, prior to the more directed discussion of FIG. 3, various background fabrication stages are described herein to more fully enable the semiconductor IC device 100.

To fabricate semiconductor IC device 100, nanolayers may be initially formed upon a substrate structure. For example, alternating sacrificial nanolayers (not shown) and active nanolayers (not shown) may be formed upon a substrate structure 110. The substrate structure 110 may be a bulk-semiconductor substrate. In one example, the bulk-semiconductor substrate may be a silicon-containing material. Illustrative examples of silicon-containing materials suitable for the bulk-semiconductor substrate include, but are not limited to, silicon, silicon germanium, silicon germanium carbide, silicon carbide, polysilicon, epitaxial silicon, amorphous silicon, and multi-layers thereof. Although silicon (Si) is the predominantly used semiconductor material in wafer fabrication, alternative semiconductor materials can be employed, such as, but not limited to, gallium arsenide, gallium nitride, cadmium telluride, zinc selenide, and III-V compound semiconductors and/or II-VI compound semiconductors. III-V compound semiconductors are materials that include at least one element from Group III of the Periodic Table of Elements and at least one element from Group V of the Periodic Table of Elements. II-VI compound semiconductors are materials that include at least one element from Group II of the Periodic Table of Elements and at least one element from Group VI of the Periodic Table of Elements.

In an implementation, the substrate structure 110 includes an upper substrate (not shown), a lower substrate (not shown), and an etch stop layer (not shown) between the upper substrate and the lower substrate. The upper substrate and the lower substrate may be comprised of any other suitable material(s) than those listed above, and the etch stop layer may be a dielectric material with etch selectivity to one or both of the upper substrate and/or the lower substrate. In one example, the etch stop layer may be an oxide and the substrate structure 110 may be referred to as a buried oxide (BOX) substrate. In another example, the lower substrate may be composed of Si. The etch stop layer may be composed of Silicon Germanium (SiGe) and may be epitaxially grown from the top surface of lower substrate, and the upper substrate may be composed of Si and may be epitaxially grown from the top surface of etch stop layer.

Nanolayers may be formed over the substrate structure 110 by forming a series of alternating sacrificial nanolayers and active nanolayers thereupon. In certain examples, certain layer(s) may be formed between the upper surface of the substrate structure 110 and the bottommost sacrificial nanolayer. The sacrificial nanolayers may be SiGe sacrificial nanolayers and the active nanolayers may be Si nanolayers. The sacrificial nanolayers can have Ge % ranging from 20% to 45%. In an implementation, the alternating sacrificial nanolayers may be formed by epitaxially growing one layer and then the next until the desired number and desired thicknesses of the layers are achieved. Any number of alternating nanolayers can be provided. Epitaxial materials can be grown from gaseous or liquid precursors. Epitaxial materials can be grown using vapor-phase epitaxy (VPE), molecular-beam epitaxy (MBE), liquid-phase epitaxy (LPE), or other suitable process.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases are controlled and the system parameters are set so that the depositing atoms arrive at the deposition surface of the semiconductor substrate with sufficient energy to move about on the surface such that the depositing atoms orient themselves to the crystal arrangement of the atoms of the deposition surface. Therefore, an epitaxially grown semiconductor material has substantially the same crystalline characteristics as the deposition surface on which the epitaxially grown material may be formed. For example, an epitaxially grown semiconductor material deposited on a (100) orientated crystalline surface will take on a (100) orientation. In some embodiments, epitaxial growth and/or deposition processes are selective to forming on semiconductor surfaces, and generally do not deposit material on exposed surfaces, such as silicon dioxide or silicon nitride surfaces.

Although it is specifically contemplated that the sacrificial nanolayers can be formed from SiGe and that the active nanolayers can be formed from Si, it should be understood that any appropriate materials can be used instead, as long as the semiconductor materials have etch selectivity with respect to one or more of the others, as is consistent with the description of the fabrication stages herein.

Although it is specifically contemplated that the sacrificial nanolayers and the active nanolayers are formed by epitaxial growth, such nanolayers can be formed by another or different and appropriate deposition mechanism, such as chemical vapor deposition (CVD), physical vapor deposition (PVD), atomic layer deposition (ALD), or gas cluster ion beam (GCIB) deposition, or the like.

In certain embodiments, the nanolayers have a vertical thickness ranging, for example, from approximately 3 nm to approximately 20 nm. In certain embodiments, the nanolayers have a vertical thickness ranging, for example, from approximately 3 nm to approximately 20 nm. Although the range of 3-20 nm is cited as an example range of thickness of the nanolayers, other thickness of these nanolayers may be used. In certain examples, certain of the nanolayers may have different thicknesses relative to one another. In certain examples, it may be desirable to have a small vertical spacing (VSP) between adjacent active nanolayers to reduce the parasitic capacitance and to improve circuit speed. For example, the VSP (the distance between vertically adjacent active nanolayers) may range from 5 nm to 15 nm. However, the VSP must be of a sufficient value to accommodate the formation of a gate that is to be formed in the spaces created by later removal of respective portions of the sacrificial nanolayers.

Further, to fabricate semiconductor IC device 100, the nanolayers are patterned into nanolayer stacks, and shallow trench isolation (STI) regions are formed. For example, the nanolayers may be patterned into nanolayer stacks (not shown) and STI regions 130 may be formed. To form one or more nanolayer stacks, a mask layer (not shown) may be formed on the uppermost nanolayer. The mask layer may be comprised of any suitable mask material(s). The mask layer may be patterned and used to perform the nanolayer stack patterning process. In the nanolayer stack patterning process, any suitable material removal process (e.g., reactive ion etching or RIE) may be used to remove portions of the alternating nanolayers down to the level of the substrate structure 110, or the like. Following the nanolayer stack patterning process, one or more nanolayer stacks are formed. Subsequently, the mask layer may be removed.

The removal of undesired portion(s) of the alternating nanolayers may further remove undesired portions of substrate structure 110 that are adjacent to respective footprints of nanolayer stacks to form STI region openings. The etch may be timed or otherwise controlled to stop the removal of the substrate structure 110 such that the depth or bottom of the one or more STI region openings has a predetermined or desired dimension. For example, the depth or bottom of the one or more STI region openings may be above the etch stop layer, as depicted. In some examples, the etch to form the nanolayer stacks may utilize the etch stop layer to stop the etch and form the bottom well of the one or more STI region openings.

A STI region 130 may be formed upon and/or within the substrate structure 110 within respective STI region openings. The STI regions 130 may be formed by depositing electrical dielectric material(s) within respective STI region opening(s) that are adjacent to the one or more nanolayer stacks. A top surface of the one or more STI regions 130 may be coplanar with a top surface of the substrate structure 110 (not shown in the depicted cross-sections). The one or more STI regions 130 may have a volume and/or geometry that sufficiently electrically isolates components or features of neighboring transistors, or the like, may sufficiently electrically isolate neighboring nanolayer stacks, and/or may sufficiently electrically isolate neighboring active regions. For clarity, a particular STI region 130 may separate and adequately electrically isolate neighboring transistors (e.g., STI region 130 may separate another lower (not shown) from the depicted lower transistor 112).

In an example, the STI region(s) 130 may be formed by depositing a STI liner within the STI region openings. Subsequently, STI region(s) 130 may be further formed by depositing a STI dielectric material upon a STI liner. An etch back, recess, or the like, may occur to remove undesired or over formed STI liner and/or STI dielectric material, such that the top surface of the STI region(s) 130 may be coplanar with a top surface of the substrate structure 110. STI liner may be composed of but not limited to a nitride, low-K nitride (i.e., a nitride material with a lower dielectric constant relative to SiN), or the like. The STI dielectric material may be composed of but not limited to an oxide, low-K oxide (i.e., an oxide material with a lower dielectric constant relative to SiO₂), or the like.

Further, to fabricate semiconductor IC device 100, one or more lower sacrificial gate structures (not shown) may be formed, and lower gate spacers (not shown) may be formed. Further, source/drain (S/D) recesses may be formed within the one or more nanolayer stacks between the lower gate spacers of neighboring lower sacrificial gate structures. Further, the sacrificial nanolayers may be indented and a respective lower inner spacer (not shown) may be formed within respective indents. Further, a bottom transistor backside contact placeholder may be formed within respective source/drain (S/D) recesses. Further, a bottom S/D region may be formed upon respective backside contact placeholders. Further, a bottom interlayer dielectric (ILD) and lower gate cut regions may be formed.

For example, one or more lower sacrificial gate structures (not shown) may be formed and may include a lower sacrificial gate liner (not shown), a lower sacrificial gate (not shown), and a lower sacrificial gate cap (not shown). The lower sacrificial gate structures may be formed by initially depositing a lower sacrificial gate liner layer (e.g., a dielectric, oxide, or the like) upon the one or more STI regions 130 and upon and around the one or more nanolayer stacks. The lower sacrificial gate structures may further be formed by subsequently depositing a lower sacrificial gate layer (e.g., amorphous silicon, or the like) upon the lower sacrificial gate liner layer. The thickness of the lower sacrificial gate layer may be such that the top surface of the lower sacrificial gate layer may be above the top surface of the one or more nanolayer stacks. The lower sacrificial gate structures may further be formed by forming a gate cap layer upon the lower sacrificial gate layer. The gate cap layer may be formed by depositing a mask material, such as a hard mask material, such as silicon nitride, silicon oxide, combinations thereof, or the like, upon the lower sacrificial gate layer. The gate cap layer may be composed of one or more layers of masking materials to protect the lower sacrificial gate layer and/or other underlying materials during subsequent processing of semiconductor IC device 100.

The one or more lower sacrificial gate structures may further be formed by patterning the gate cap layer, lower sacrificial gate layer, and lower sacrificial gate liner by, for example, using lithography and etch processes to remove undesired portions and retain desired portion(s), respectively. The retained portion(s) of the gate cap layer, lower sacrificial gate layer, and lower sacrificial gate liner may form the lower sacrificial gate liner (not shown), the lower sacrificial gate (not shown), and the lower sacrificial gate cap (not shown), respectively, of each of the one or more lower sacrificial gate structures.

One or more lower sacrificial gate structures can be formed on targeted regions or areas of semiconductor IC device 100 to define the gate length of one or more bottom transistors and to provide sacrificial material for yielding targeted bottom transistor structure(s) in subsequent processing.

Further, to fabricate semiconductor IC device 100, lower gate spacers (not shown) may be formed. The gate spacer(s) may be formed upon the sidewall(s) of the lower sacrificial gate structures, upon the STI region(s) 130, and around the one or more nanolayer stacks. The gate spacer(s) may be formed by a conformal deposition of a dielectric material, such as silicon nitride, SiBCN, SiNC, SiN, SiCO, SiNOC, or a combination thereof, or the like, upon STI regions 130, upon and around the one or more lower sacrificial gate structures, and upon and around the one or more nanolayer stack(s). Subsequently, undesired portions of dielectric material may be removed while desired portions the dielectric material may be retained and thereby form the gate spacer(s). The undesired portions of dielectric material may be removed by a directional ion etch, such as a reactive ion etch (RIE).

Further, to fabricate semiconductor IC device 100, source/drain (S/D) recesses may be formed within the one or more nanolayer stacks between lower gate spacers of neighboring lower sacrificial gate structures. In other words, a single nanolayer stack may be separated, by a S/D recess, into multiple nanolayer stacks each located underneath a respective lower sacrificial gate structure. Further, sacrificial nanolayers may be indented and a respective lower inner spacer may be formed in each indent.

The one or more S/D recesses may be formed between adjacent lower sacrificial gate structures by removing respective portions of the sacrificial nanolayers and active nanolayers, that are between lower gate spacers of adjacent or neighboring lower sacrificial gate structures. The one or more S/D recesses may be formed to a depth to stop at the top surface of the substrate structure 110 (e.g., the top surface of upper substrate, or the like), the top surface of STI regions 130, or the like. Alternatively, as depicted, the one or more S/D recesses may be formed to a depth within the upper substrate above the etch stop layer so that backside contact placeholder(s) 140 may be formed therewithin.

The undesired portions of sacrificial nanolayers and active nanolayers may be removed by etching or other subtractive removal techniques. The top surface of the substrate structure 110 may be used as an etch stop or other etch parameters may be controlled to stop the material removal at the substrate structure 110. As the lower gate spacers and the lower sacrificial gate structures may be utilized to protect the underlying portions of sacrificial nanolayers, active nanolayers, respective sidewalls of the nanolayer stacks may be substantially coplanar and substantially vertical with the outer sidewalls of the lower gate spacers, there above.

As used herein, “substantially vertical” sidewalls deviate from a direction normal to a major surface (e.g., top surface, etc.) of the substrate by no more than 5°, e.g., 0°, 1°, 2°, 3°, 4°, or 5°, including ranges between any of the foregoing values.

Further, to fabricate semiconductor IC device 100, horizontal, or lateral indents may be formed by laterally or horizontally (e.g., into and/or out of the page of the depicted Y1 cross-section) removing respective portions of sacrificial nanolayers within the nanolayer stacks. The indents may be formed by a reactive ion etch (RIE) process, which can remove portions of the sacrificial nanolayers. The horizontal depth of the indents may be chosen to set a length for a replacement gate structure that may be formed in place of one lower sacrificial gate structure. When the sacrificial nanolayers are composed of SiGe and when active nanolayers are Si, the directional RIE can use a boron-based chemistry or a chlorine-based chemistry, for example, which recesses or removes the exposed end portions of sacrificial nanolayers (e.g., end portions of sacrificial nanolayers generally below the gate spacer) selective to the Si active nanolayers. In alternative implementations, when sacrificial nanolayers are not SiGe and when active nanolayers are not Si, the directional etch of the sacrificial nanolayers may generally be selective to the active nanolayers, lower gate spacers, STI regions 130, and/or substrate structure 110.

Further, to fabricate semiconductor IC device 100, a respective lower inner spacer (not shown) may be formed within each indent. The one or more lower inner spacers can be formed by ALD or CVD or any other suitable deposition technique that deposits a dielectric material within the indent(s), thereby forming the lower inner spacer(s). In some examples, the lower inner spacer(s) are composed of a low-κ dielectric material (a material with a lower dielectric constant relative to SiO₂), SiN, SiO, SiBCN, SiOCN, SiCO, etc. or any other suitable dielectric material. In certain implementations, after the formation of the lower inner spacer(s), an isotropic etch process may be performed to create substantially vertical sidewalls of the lower inner spacer(s) that are coplanar with the substantially vertical sidewalls of the active nanolayers, of the lower gate spacers, or the like.

Further, to fabricate semiconductor IC device 100, one or more lower transistor 112 backside contact placeholders 140 are formed within the substrate structure 110 in between adjacent lower sacrificial gate structures within a respective S/D recess. In one example, the one or more backside contact placeholders 140 may be formed only in locations in which a backside contact is to be formed. In an alternative example, a respective backside contact placeholder 140 may be formed in each lower transistor 112 S/D region location.

If the S/D recesses are not already of sufficient depth to form the backside contact placeholders 140 within the substrate structure 110, the one or more backside contact placeholders 140 may be formed by initially forming one or more backside contact placeholder cavities within the substrate structure 110 generally in between adjacent lower sacrificial gate structures (e.g., the vertical depth of the one or more S/D recesses may be increased). For example, the one or more backside contact placeholder(s) cavities may be formed by a subtractive removal technique, such as an etch, that removes associated portion(s) of the upper substrate. The etch may be timed or otherwise controlled to stop the removal of the upper substrate such that the depth or bottom of the one or more backside contact placeholder(s) cavities are above the etch stop layer.

The one or more backside contact placeholders 140 may be further formed by epitaxially growing an epitaxial material from exposed substrate structure 110 surface(s) within the one or more backside contact placeholder(s) cavities. In some embodiments, epitaxial growth and/or deposition processes may be selective to forming on the semiconductor surfaces of the upper substrate, and may not deposit material on dielectric surfaces, such as silicon dioxide or silicon nitride surfaces. In some embodiments, the epitaxial growth of the one or more backside contact placeholders 140 may overgrow above the top surface of the substrate structure 110 or above the top surface of STI regions 130. In an example, the epitaxial material of the one or more backside contact placeholders 140 may be chosen to be etch selective to the material of the lower S/D region(s) 141, the material of the upper substrate, or the like. In another example, a separation layer (not shown) (e.g., a Si epitaxially grown layer, or the like) may be formed upon the top surface of the backside contact placeholders 140. For example, the one or more backside contact placeholders 140 may be SiGe and a Si separation layer may be epitaxially grown from the top surface of the SiGe backside contact placeholders 140. Respective top surfaces of the backside contact placeholders 140 (or separation layer thereupon) may be substantially horizontal and below the bottom surface of the bottommost active nanolayer (e.g., to enable contact between such active nanolayer and the bottom S/D region 141).

Further, to fabricate semiconductor IC device 100, respective lower S/D region 141 may be formed upon a backside contact placeholder 140. The lower S/D region 141 forms either a source or a drain, respectively, of respective lower transistor(s) 112, such as a GAA FET, and may be connected to respective a side or end surface of the active nanolayers of a nanolayer stack. The S/D region 141 may be composed of a semiconductor material and a dopant. As used herein, a “source/drain” region can be a source region or a drain region depending on subsequent wiring and application of voltages during operation of the transistor. The semiconductor material that provides each lower S/D region 141 may be composed of one of the semiconductor materials mentioned above for the semiconductor structure. The semiconductor material that provides the lower S/D region 141 can be compositionally the same, or compositionally different from each active nanolayers. The dopant that may be present in the lower S/D region 141 can be either a p-type dopant or an n-type dopant. The term “p-type” refers to the addition of impurities to an intrinsic semiconductor that creates deficiencies of valence electrons. In a silicon-containing semiconductor material, examples of p-type dopants, i.e., impurities, include, but are not limited to, boron, aluminum, gallium, phosphorus and indium. “n-type” refers to the addition of impurities that contributes free electrons to an intrinsic semiconductor. In a silicon containing semiconductor material, examples of n-type dopants, i.e., impurities, include, but are not limited to, antimony, arsenic and phosphorous. In one example, each of the S/D regions can have a dopant concentration of from 4×10²⁰ atoms/cm³ to 3×10²¹ atoms/cm³.

The one or more lower S/D regions 141 may be epitaxially grown or formed and may, therefore, include one or more (111) orientated crystallographic side surfaces 147. Further, one or more lower S/D regions 141 may include one or more (100) orientated crystallographic top surfaces 149.

In some examples, the lower S/D regions 141 are formed by in-situ doped epitaxial growth. The use of an in-situ doping process is merely an example. For instance, one may instead employ an ex-situ process to introduce dopants into the source and drains. Other doping techniques can be used to incorporate dopants in the bottom source/drain region. Dopant techniques include but are not limited to, ion implantation, gas phase doping, plasma doping, plasma immersion ion implantation, cluster doping, infusion doping, liquid phase doping, solid phase doping, in-situ epitaxy growth, or any suitable combination of those techniques. In examples, the S/D epitaxial growth conditions that promote in-situ Boron doped SiGe for p-type transistor and phosphorus or arsenic doped silicon or Si:C for n-type transistors.

In some examples, the epitaxial growth that forms the one or more lower S/D region 141 occurs or may be promoted from the top surface of upper substrate or alternatively from the upper surface of backside contact placeholders 140 (or separation layer thereupon), while epitaxial growth may be limited or does not occur from neighboring STI regions 130.

In some embodiments, epitaxial growth to form the one or more lower S/D regions 141 may overgrow above the upper surface of the lower sacrificial gate structure(s) and be subsequently recessed such that the top surface of the lower S/D region 141 may be substantially horizontal and above the top surface of the topmost active nanolayer within the nanolayer stacks (e.g., to enable contact between such active nanolayer and the lower S/D region 141).

Further, to fabricate semiconductor IC device 100, a lower interlayer dielectric (ILD) 150 may be formed. For example, a blanket lower ILD 150 material may be deposited over the S/D region(s) 141, over the STI region(s) 130, over the lower sacrificial gate structures, and over the lower gate spacers associated with adjacent lower sacrificial gate structures.

The lower ILD 150 can be any suitable material, such as, for example, porous silicates, carbon doped oxides, silicon dioxides, silicon nitrides, silicon oxynitrides, OPL, or other dielectric materials. Any known manner of forming the lower ILD 150 can be utilized. The lower ILD 150 can be formed using, for example, CVD, PECVD, ALD, flowable CVD, spin-on dielectrics, or PVD.

In an example, the lower ILD 150 may be formed to a thickness above the top surface of the lower sacrificial gate structures. Subsequently, a planarization process, such as a CMP, may be performed to remove excess lower ILD 150 material and to remove the lower sacrificial gate caps of the lower sacrificial gate structures, thereby exposing the lower sacrificial gate thereunder. The planarization may also partially remove some of the lower sacrificial gates or may at least expose the lower sacrificial gate of the lower sacrificial gate structures. The CMP may create a substantially planar or substantially horizontal top surface for the semiconductor IC device 100. In other words, the respective top surfaces of the lower ILD 150, lower gate spacers, lower sacrificial gates, etc. may be substantially coplanar and/or substantially horizontal.

Lower gate cut region(s) may be formed within the sacrificial gate structure. For example, a gate cut opening may be formed within the sacrificial gate structure in between associated lower gate spacer(s). The gate cut opening may expose an upper surface of a portion of the gate liner, an upper surface of a portion of the STI region(s) 130, an upper surface of substrate structure 110, or the like.

The gate cut opening may be formed by lithography and etch process, where a mask may be applied and patterned. An opening in the patterned mask may expose the portion of the underlying lower sacrificial gate structure to be removed while other protected portions of the lower sacrificial gate structure thereunder may be protected and retained. Lower gate cut region(s) that effectively separate a long sacrificial gate structure into electrically separate sacrificial gate structure may be further formed by depositing dielectric material such as silicon nitride (SiN), a combination of SiN and Silicon Dioxide (SiO₂), or the like, within the gate cut opening. Subsequently, excess mask material and/or excess lower gate cut region material may be removed and planarized by e.g., a CMP. As such, respective top surfaces the lower sacrificial gate structure, lower gate spacer(s), lower ILD 150, and lower gate cut region(s) may be coplanar.

Further, to fabricate semiconductor IC device 100, the semiconductor IC device 100 may be fabricated by bonding the top transistor nanolayers to the existing structure. For example, top transistor nanolayers (not shown), which includes alternating active nanolayers (not shown) and sacrificial nanolayers (not shown) may be bonded to the existing semiconductor IC device 100 by a bonding layer 170. In such process, a second wafer that includes a second substrate (not shown) and the top transistor nanolayers, formed upon the second wafer, may be bonded to the existing semiconductor IC device 100. The two wafers may be bonded by bonding layer 170, which may be e.g., a bonding oxide. After wafer-to-wafer bonding, the second substrate may be removed, and the top transistor nanolayers may be retained and may be effectively bonded to the existing semiconductor IC device 100. The top transistor nanolayers may be composed of similar materials and have similar geometries relative to the bottom transistor nanolayers.

Further, to fabricate semiconductor IC device 100, the top transistor nanolayers may be patterned into nanolayer stacks. For example, the top transistor nanolayers may be patterned into nanolayer stacks (not shown). To form one or more nanolayer stacks, a mask layer (not shown) may be formed on the uppermost nanolayer of the top transistor nanolayers. The mask layer may be comprised of any suitable mask material(s). The mask layer may be patterned and used to perform the nanolayer stack patterning process. In the nanolayer stack patterning process, any suitable material removal process (e.g., reactive ion etching or RIE) may be used to remove portions of the alternating top transistor nanolayers down to the level of the bonding layer 170, or the like. Following the nanolayer stack patterning process, one or more nanolayer stacks are formed. Subsequently, the mask layer may be removed. A horizontal width of a first nanolayer stack may define a horizontal dimension (e.g., left to right) and a perpendicular horizontal dimension (e.g., into and out of the page) of upper transistor active region 104.

Further, to fabricate semiconductor IC device 100, one or more upper sacrificial gate structures (not shown) may be formed. Further, upper gate spacers (not shown) may be formed. Further, the upper sacrificial nanolayers may be indented and a respective upper inner spacer (not shown) may be formed within respective indents.

The one or more upper sacrificial gate structures (not shown) may be formed over the one or more nanolayer stacks and may include an upper sacrificial gate liner (not shown), a upper sacrificial gate (not shown), and a upper sacrificial gate cap (not shown). The upper sacrificial gate structures may be formed by initially depositing an upper sacrificial gate liner layer (e.g., a dielectric, oxide, or the like) upon the bonding layer 170 and upon and around the one or more nanolayer stacks. The upper sacrificial gate structures may further be formed by subsequently depositing an upper sacrificial gate layer (e.g., amorphous silicon, or the like) upon the upper sacrificial gate liner layer. The thickness of the upper sacrificial gate layer may be such that the top surface of the upper sacrificial gate layer may be above the top surface of the one or more nanolayer stacks. The upper sacrificial gate structures may further be formed by forming a gate cap layer upon the upper sacrificial gate layer. The gate cap layer may be formed by depositing a mask material, such as a hard mask material, such as silicon nitride, silicon oxide, combinations thereof, or the like, upon the upper sacrificial gate layer. The gate cap layer may be composed of one or more layers of masking materials to protect the upper sacrificial gate layer and/or other underlying materials during subsequent processing of semiconductor IC device 100.

The one or more upper sacrificial gate structures may further be formed by patterning the gate cap layer, upper sacrificial gate layer, and upper sacrificial gate liner by, for example, using lithography and etch processes to remove undesired portions and retain desired portion(s), respectively. The retained portion(s) of the gate cap layer, upper sacrificial gate layer, and upper sacrificial gate liner may form the upper sacrificial gate liner (not shown), the upper sacrificial gate (not shown), and the upper sacrificial gate cap (not shown), respectively, of each of the one or more upper sacrificial gate structures.

One or more upper sacrificial gate structures can be formed on targeted regions or areas of semiconductor IC device 100 to define the gate length of one or more upper transistors and to provide sacrificial material for yielding targeted upper transistor structure(s) in subsequent processing. In embodiments, a respective upper sacrificial gate structure may be formed in line with a particular lower sacrificial gate structure.

The upper gate spacer(s) may be formed upon the sidewall(s) of the upper sacrificial gate structures, upon the bonding layer 170, and around the one or more nanolayer stacks. The upper gate spacer(s) may be formed by a conformal deposition of a dielectric material, such as silicon nitride, SiBCN, SiNC, SiN, SiCO, SiNOC, or a combination thereof, or the like, upon bonding layer 170, upon and around the one or more upper sacrificial gate structures, and upon and around the one or more nanolayer stack(s). Subsequently, undesired portions of dielectric material may be removed while desired portions the dielectric material may be retained and thereby form the upper gate spacer(s). The undesired portions of dielectric material may be removed by a directional ion etch, such as a reactive ion etch (RIE).

The upper source/drain (S/D) recesses may be formed within the one or more nanolayer stacks between upper gate spacers of neighboring upper sacrificial gate structures. In other words, a single nanolayer stack may be separated, by an upper S/D recess, into multiple nanolayer stacks each located underneath a respective upper sacrificial gate structure. The one or more upper S/D recesses may be formed between adjacent upper sacrificial gate structures by removing respective portions of the sacrificial nanolayers and active nanolayers that are between upper gate spacers of adjacent or neighboring upper sacrificial gate structures. The one or more upper S/D recesses may be formed to a depth to stop at the top surface of the bonding layer 170, or the like.

The undesired portions of sacrificial nanolayers and active nanolayers may be removed by etching or other subtractive removal techniques. The top surface of the bonding layer 170 may be used as an etch stop or other etch parameters may be controlled to stop the material removal at the bonding layer 170. As the upper gate spacers and the upper sacrificial gate structures may be utilized to protect the underlying portions of sacrificial nanolayers, active nanolayers, respective sidewalls of the nanolayer stacks may be substantially coplanar and substantially vertical with the outer sidewalls of the upper gate spacers, there above.

Further, sacrificial nanolayers may be indented and a respective upper inner spacer may be formed in each indent. For example, horizontal or lateral indents may be formed by laterally or horizontally (e.g., into and/or out of the page of the depicted Y1 cross-section) removing respective portions of sacrificial nanolayers within the nanolayer stacks. The indents may be formed by a reactive ion etch (RIE) process, which can remove portions of the sacrificial nanolayers. The horizontal depth of the indents may be chosen to set a length for a replacement gate structure that may be formed in place of one upper sacrificial gate structure. When the sacrificial nanolayers are composed of SiGe and when active nanolayers are Si, the directional RIE can use a boron-based chemistry or a chlorine-based chemistry, for example, which recesses or removes the exposed end portions of sacrificial nanolayers (e.g., end portions of sacrificial nanolayers generally below the gate spacer) selective to the Si active nanolayers. In alternative implementations when sacrificial nanolayers are not SiGe and when active nanolayers are not Si, the directional etch of the sacrificial nanolayers may generally be selective to the active nanolayers, upper gate spacers, and/or bonding layer 170.

A respective upper inner spacer (not shown) may be formed within each indent. The one or more upper inner spacers can be formed by ALD or CVD or any other suitable deposition technique that deposits a dielectric material within the indent(s), thereby forming the upper inner spacer(s). In some examples, the upper inner spacer(s) are composed of a low-K dielectric material, SiN, SiO, SiBCN, SiOCN, SiCO, etc. or any other suitable dielectric material. In certain implementations, after the formation of the upper inner spacer(s), an isotropic etch process may be performed to create substantially vertical sidewalls of the upper inner spacer(s) that are coplanar with the substantially vertical sidewalls of the active nanolayers, of the upper gate spacers, or the like.

Further, to fabricate semiconductor IC device 100, respective upper S/D regions 192 may be formed. The upper S/D region 192 forms either a source or a drain, respectively, of respective upper transistor, such as a GAA FET, and may be connected to respective a side or end surface of the active nanolayers of the upper nanolayer stack. The upper S/D region 192 may be composed of a semiconductor material and a dopant. The semiconductor material that provides each upper S/D region 192 may be composed of one of the semiconductor materials mentioned above for the semiconductor structure. The semiconductor material that provides the upper S/D region 192 can be compositionally the same, or compositionally different from each active nanolayers. The dopant that may be present in the upper S/D region 192 can be either a p-type dopant or an n-type dopant. In one example, each upper S/D region 192 can have a dopant concentration of from 4×10²⁰ atoms/cm³ to 3×10²¹ atoms/cm³.

The one or more upper S/D regions 192 may be epitaxially grown or formed and may, therefore, include one or more (111) orientated diamond like crystallographic surfaces 177. Further, one or more upper S/D regions 192 may include one or more (100) orientated crystallographic top surfaces 179. In some examples, the upper S/D regions 192 are formed by in-situ doped epitaxial growth. The use of an in-situ doping process is merely an example. For instance, one may instead employ an ex-situ process to introduce dopants into the source and drains. Other doping techniques can be used to incorporate dopants in the upper source/drain region 192. In some embodiments, epitaxial growth to form the one or more upper S/D regions 192 may overgrow above the upper surface of the upper sacrificial gate structure(s) and be subsequently recessed such that the top surface of the upper S/D region 192 may be substantially horizontal and above the top surface of the topmost active nanolayer within the nanolayer stacks (e.g., to enable contact between this active nanolayer and the upper S/D region 192).

Further, to fabricate semiconductor IC device 100, an upper interlayer dielectric (ILD) 194 may be formed. For example, a blanket upper ILD 194 material may be deposited over the upper S/D region(s) 192, over the bonding layer 170, over the upper sacrificial gate structures, and over the upper gate spacers associated with adjacent upper sacrificial gate structures.

The upper ILD 194 can be any suitable material, such as, for example, porous silicates, carbon doped oxides, silicon dioxides, silicon nitrides, silicon oxynitrides, OPL, or other dielectric materials. Any known manner of forming the upper ILD 194 can be utilized. The upper ILD 194 can be formed using, for example, CVD, PECVD, ALD, flowable CVD, spin-on dielectrics, or PVD.

In an example, the upper ILD 194 may be formed to a thickness above the top surface of the upper sacrificial gate structures. Subsequently, a planarization process, such as a CMP, may be performed to remove excess upper ILD 194 material and to remove the upper sacrificial gate caps of the upper sacrificial gate structures, thereby exposing the upper sacrificial gate thereunder. The planarization may also partially remove some of the upper sacrificial gates or may at least expose the upper sacrificial gate of the upper sacrificial gate structures. The CMP may create a substantially planar or substantially horizontal top surface for the semiconductor IC device 100. In other words, the respective top surfaces of the upper ILD 194, upper gate spacers or upper sacrificial gates, etc. may be substantially coplanar and/or substantially horizontal.

Further, to fabricate semiconductor IC device 100, upper gate cut region(s) (not shown) may be formed within the upper sacrificial gate structures. For example, a gate cut opening may be formed within the upper sacrificial gate structure in between associated upper gate spacer(s). The gate cut opening may expose an upper surface of a portion of the gate liner, an upper surface of a portion of the bonding layer 170, or the like.

The gate cut opening may be formed by lithography and etch process, where a mask may be applied and patterned. An opening in the patterned mask may expose the portion of the underlying upper sacrificial gate structure to be removed while other protected portions of the upper sacrificial gate structure thereunder may be protected and retained. Upper gate cut region(s) may be further formed by depositing dielectric material such as silicon nitride (SiN), a combination of SiN and Silicon Dioxide (SiO₂), or the like, within the gate cut opening. Subsequently, excess mask material and/or excess upper gate cut region material may be removed and planarized by e.g., a CMP. As such, respective top surfaces the upper sacrificial gate structure, upper gate spacer(s), and upper gate cut region(s) may be coplanar.

Further, to fabricate semiconductor IC device 100, the upper sacrificial gate structures may be patterned to expose the underlying lower sacrificial gate structures. For example, one or more replacement gate opening(s) (not shown) may be formed within the upper sacrificial gate structure(s) and expose a respective portion(s) of lower sacrificial gate structure(s).

The one or more replacement gate opening(s) may be formed by lithography and etch process, where a mask (not shown) may be applied and patterned. An opening in the patterned mask may expose the portion of the underlying upper sacrificial gate structure to be removed between upper gate spacers, while other protected portions of upper sacrificial gate structure thereunder may be protected and retained. The one or more replacement gate opening(s) may be formed to a depth through bonding layer 170 to expose at least a portion of the lower upper sacrificial gate structure(s). For example, the etch utilized to remove the unprotected portion(s) of upper sacrificial gate structure(s) and respective portion(s) of bonding layer 170, there below, may be timed to stop at or within the lower upper sacrificial gate structure(s).

Further, to fabricate semiconductor IC device 100, the upper sacrificial gate structures and the lower sacrificial gate structures may be removed which may form a replacement gate structure opening. The upper sacrificial gate structures and the lower sacrificial gate structures may be removed by a selective etch of the upper gate and lower gate material through the one or more replacement gate opening(s).

After the removal of the sacrificial gate structures, there are void spaces between the retained active semiconductor nanolayers. Therefore, the active semiconductor nanolayers and may be referred to as released. It should be appreciated that during the removal of the sacrificial gate structures appropriate etchants are used that do not significantly remove material of active semiconductor nanolayers and, bonding layer 170, upper and lower gate spacers, upper and lower inner spacers, and upper and lower gate cut region(s), or the like.

Further, to fabricate semiconductor IC device 100, replacement gate structure(s) (not shown) are formed in place of the removed lower sacrificial gate structure(s) around one or more active semiconductor nanolayers and in place of the removed upper sacrificial gate structure(s) around the released active semiconductor nanolayers. For clarity, the replacement gate structure may be shared by the upper transistor 114 and the lower transistor 112 (i.e., the same replacement gate structure may be around the upper active semiconductor nanolayers and the lower active semiconductor nanolayers).

A replacement gate structure may be formed by initially forming an interfacial layer (not shown) on the interior surfaces of the replacement gate opening. Then, a high-κ layer (not shown) may be formed to cover the surfaces of exposed surfaces of the interfacial layer. The high-κ layer can be deposited by any suitable techniques, such as ALD, CVD, metal-organic CVD (MOCVD), physical vapor deposition (PVD), thermal oxidation, combinations thereof, or other suitable techniques. A high-κ dielectric material is a material with a higher dielectric constant than that of SiO₂, and can include e.g., LaO, AlO, ZrO, TiO, Ta₂O₅, Y₂O₃, SrTiO₃(STO), BaTiO₃ (BTO), BaZrO, HfZrO, HfLaO, HfSiO, LaSiO, AlSiO, HfTaO, HfTiO, (Ba,Sr)TiO₃ (BST), Al₂O₃, Si₃N₄, oxynitrides (SiON), or other suitable materials. In other examples, instead of the high-κ layer, a metal layer may be formed to cover the surfaces of exposed surfaces of the interfacial layer. The metal layer may include, e.g., Ti, Ag, Al, TiAlN, TaC, TaCN, TaSiN, Mn, Zr, TiN, TaN, Ru, Mo, Al, WN, Cu, W, or any suitable materials.

The replacement gate structure may be further formed by depositing a work function (WF) gate, which may be referred to herein as replacement gate upon the high-κ layer. The replacement gate can be comprised of metals, such as, e.g., copper (Cu), cobalt (Co), aluminum (Al), platinum (Pt), gold (Au), tungsten (W), titanium (Ti), nitride (N) or any combination thereof. The metal can be deposited by a suitable deposition process, for example, chemical vapor deposition (CVD), plasma enhanced chemical vapor deposition (PECVD), physical vapor deposition (PVD), plating, thermal or e-beam evaporation, or sputtering. In various exemplary embodiments, the height of the replacement gate can be reduced by chemical-mechanical polishing (CMP) and/or etching. Therefore, the planarization process can be provided by CMP. Other planarization process can include grinding and polishing. In general, the replacement gate sets the threshold voltage (Vt) of the upper transistors and the lower transistors. The high-κ layer may separate the replacement gate from the active semiconductor nanolayers and the active semiconductor nanolayers. Other metals may be desired to further fine tune the effective work function (eWF) and/or to achieve a desired resistance value associated with current flow through the replacement gate structure.

Further, to fabricate semiconductor IC device 100, a frontside contact ILD may be formed. For example, the frontside contact ILD (depicted as the same material as upper ILD 194) may be formed upon respective top surfaces of replacement gate structure(s), upper ILD 194, upper gate spacer(s), and upper gate cut region(s). The frontside contact ILD may be formed by depositing a dielectric material, such as, for example, porous silicates, carbon doped oxides, silicon dioxides, silicon nitrides, silicon oxynitrides, or other dielectric materials. Any appropriate deposition technique for forming the frontside contact ILD can be utilized. The frontside contact ILD can be formed using, for example, CVD, PECVD, ALD, flowable CVD, spin-on dielectrics, or PVD.

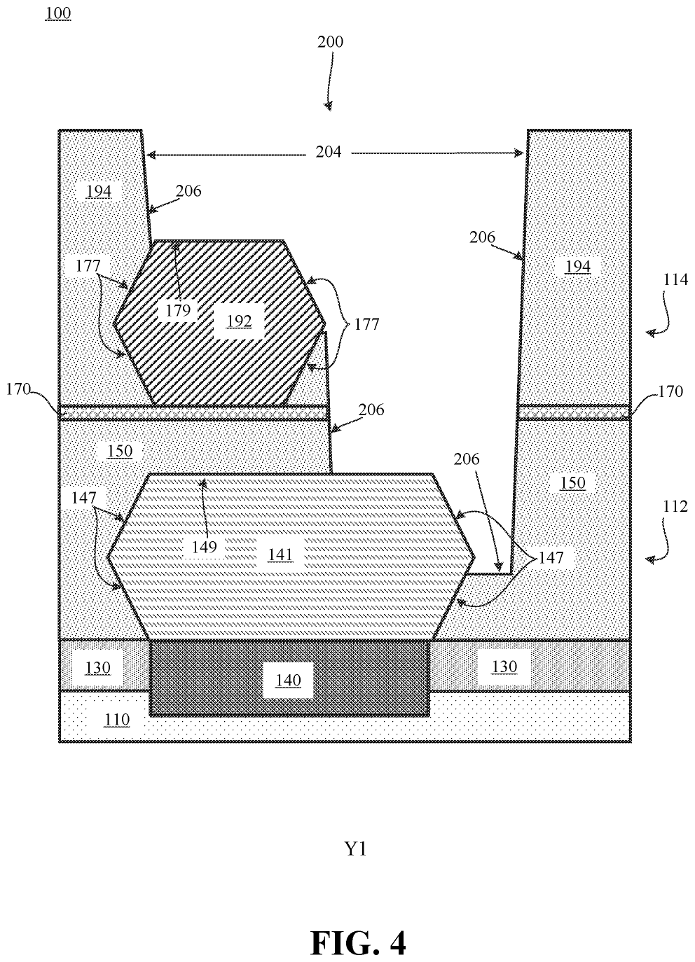

FIG. 4 depicts cross-sectional views of the semiconductor IC device 100 after fabrication operations, in accordance with embodiments of the present disclosure. In the depicted fabrication stage, one or more monolithic frontside contact opening(s) may be formed. For example, monolithic frontside contact opening 200 may be formed within the frontside contact ILD, upper ILD 194, bonding layer 170, and lower ILD 150, or the like, from the frontside (i.e., from above the semiconductor IC device 100, as depicted, downward to respective structures thereof). Each of the monolithic frontside contact openings 200 may be formed by the same or shared lithography and etch process(es), or sequential lithography and etch processes. In such process(es), a mask may be applied and patterned. An opening in the patterned mask may expose the portion of the underlying ILD to be removed while other protected portions of semiconductor IC device 100 thereunder may be protected and retained. In such process(es), the dry and wet etching processes can have etching parameters that can be tuned, such as etchants used, etching temperature, etching solution concentration, etching pressure, source power, RF bias voltage, RF bias power, etchant flow rate, to promote desired material removal and desired material retention.

The monolithic frontside contact opening 200 exposes respective portions of both the upper S/D region 192 and the lower S/D region 141 there below. Therefore, a substantially horizontal dimension 204 of the monolithic frontside contact opening 200 may be adequately large to result in the monolithic frontside contact opening 200 at least partially exposing both the upper S/D region 192 and the lower S/D region 141.

In an example, the monolithic frontside contact opening 200 at least partially exposes the upper S/D region 192. For example, the entire (100) orientated crystallographic top surface 179 may be exposed, at least one entire (111) orientated crystallographic side surface 177 of the various side surfaces 177 may be exposed, and/or one or more of the (111) orientated crystallographic side surfaces 177 may be partially exposed. In an example, the monolithic frontside contact opening 200 at least partially exposes the lower S/D region 141. For example, the (100) orientated crystallographic top surface 149 may be partially exposed, at least one entire (111) orientated crystallographic side surface 177 of the various side surfaces 177 may be exposed, and/or one or more of the (111) orientated crystallographic side surfaces 177 may be partially exposed by the monolithic frontside contact opening 200.

In an example, a depth of the monolithic frontside contact opening 200 may be controlled to result in a well or bottom surface to be above a top surface of the STI region(s) 130 and below a top surface of the lower S/D region 141. This may result in an adequate side surface area of the lower S/D region 141 being exposed by the monolithic frontside contact opening 200.

The monolithic frontside contact opening 200 may be formed by a selective etch that may remove the frontside contact ILD, upper ILD 194, bonding layer 170, and/or lower ILD 150 selective to the upper S/D region 192 and the lower S/D region 141.

In an example, the sidewalls 206 of the monolithic frontside contact opening 200 may be substantially vertical. Such substantially vertical sidewalls 206 may result when a highly directional vertical etch process (e.g., an ion based etch process, such as am RIE) is utilized to form the monolithic frontside contact opening 200. In another example, the sidewalls 206 of the monolithic frontside contact opening 200 may have linear or non-linear inward angle such that the distance between the sidewalls 206 becomes narrower in proportion to the depth monolithic frontside contact opening 200. The geometry of these sidewalls 206 may result when an isotropic or non-vertical directional etch process is utilized to form the monolithic frontside contact opening 200.

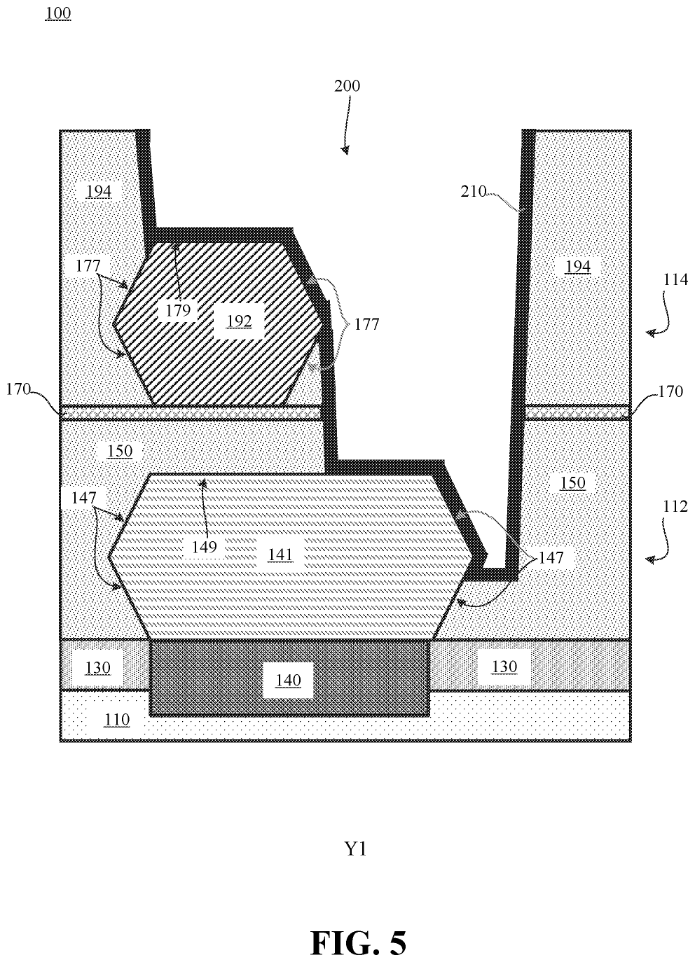

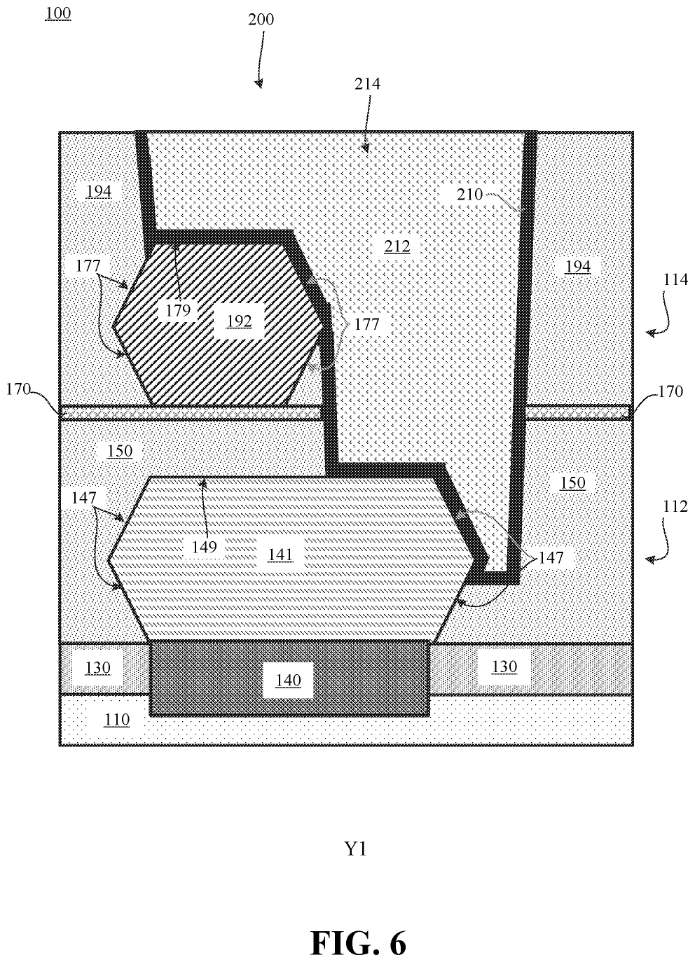

FIG. 5 depicts cross-sectional views of the semiconductor IC device 100 after fabrication operations, in accordance with embodiments of the present disclosure. In the depicted fabrication stage, a conductive liner may be formed within the monolithic contact opening(s). For example, conductive liner 210 is formed upon sidewalls 206, upon bottom surface 202, upon the exposed portion(s) of upper S/D region 192, and upon the exposed portion(s) of lower S/D region 141. The conductive liner 210 may be a diffusion barrier and may assist in limiting the conductive fill 212, as depicted in FIG. 6, from diffusing into the upper ILD 194, the lower ILD 150, or the like.

In a particular implementation, the conductive liner 210 may be formed upon the entire (100) orientated crystallographic top surface 179, upon the at least one entire (111) orientated crystallographic side surface 177 of the various side surfaces 177, and/or upon the one or more of the (111) orientated crystallographic side surfaces 177 of upper S/D region 192. Likewise, the conductive liner 210 may be formed upon the (100) orientated crystallographic top surface 149, upon the at least one entire (111) orientated crystallographic side surface 177 of the various side surfaces 177, and/or upon one or more of the (111) orientated crystallographic side surfaces 177 of lower S/D region 141.

The conductive liner 210 may include one or more conductive material layers. For example, the conductive liner 210 may be formed by depositing a barrier liner, such as Ni, NiPt, Ti, or the like, into the monolithic frontside contact opening 200, depositing an adhesion liner, such as TiN, TaN, etc. upon the barrier liner. The conductive liner 210 can be deposited by a suitable deposition process, for example, CVD, PECVD, PVD, plating, thermal or e-beam evaporation, sputtering, or the like.

FIG. 6 depicts cross-sectional views of the semiconductor IC device 100 after fabrication operations, in accordance with embodiments of the present disclosure. In the depicted fabrication stage, a conductive fill may be formed upon the conductive liner within the monolithic contact opening(s). For example, conductive fill 212 is deposited upon the conductive liner 210 within the monolithic contact opening 200.

The conductive fill 212 may be formed by depositing a conductive material, such as Al, Ru, W, Co, Cu, or the like, upon the conductive liner 210. The conductive liner 210 can be deposited by a suitable deposition process, for example, CVD, PECVD, PVD, plating, thermal or e-beam evaporation, sputtering, or the like. At the present stage of semiconductor IC device 100 fabrication, the combination of the conductive materials within the monolithic contact opening 200 may be referred to as a monolithic frontside contact 214.

Subsequently, a planarization process, such as a CMP process or a mechanical grinding process, may remove excess portions of the monolithic frontside contact 214. Subsequently, the respective top surfaces of monolithic frontside contact 214 and the frontside contact ILD may be coplanar.

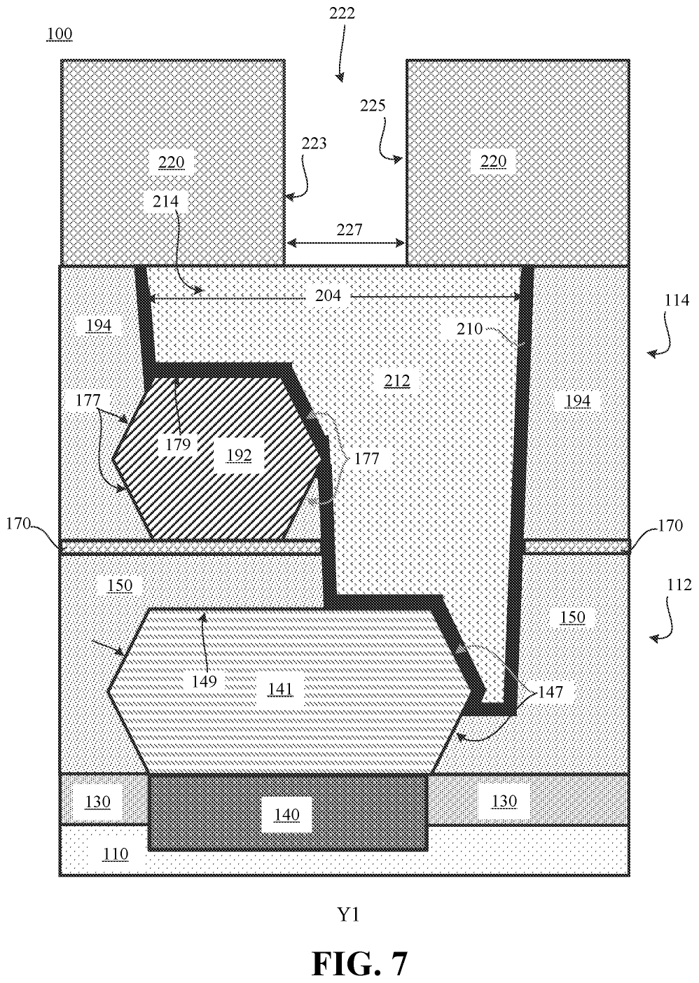

FIG. 7 depicts cross-sectional views of the semiconductor IC device 100 after fabrication operations, in accordance with embodiments of the present disclosure. In the depicted fabrication stage, a monolithic frontside contact mask may be formed and patterned. For example, monolithic frontside contact mask 220 is formed and a contact cut opening 222 is patterned therein.

The contact cut opening 222 may be formed by lithography and etch process, where the monolithic frontside contact mask 220 may be formed on monolithic frontside contact 214 and the frontside contact ILD. The monolithic frontside contact mask 220 may be comprised of any suitable mask material(s). The monolithic frontside contact mask 220 may be patterned and used to perform the monolithic frontside contact 214 cut process. The contact cut opening 222 is formed in the patterned monolithic frontside contact mask 220 and may include a sidewall 223 that is inset within the upper S/D region 192 and within the monolithic frontside contact 214 there below. The positioning of the sidewall 223 may result in a portion of the upper S/D region 192 being removed during the monolithic frontside contact 214 cut process, described in further detail below. The contact cut opening 222 may be further formed in the patterned monolithic frontside contact mask 220 to include sidewall 225 that is inset within the lower S/D region 141 and within the monolithic frontside contact 214 there below.

A substantially horizontal dimension 227 between the sidewall 223 and the sidewall 225 may be sufficiently less than the substantially horizontal dimension 204 of the monolithic frontside contact opening 200 and resulting monolithic frontside contact 214. This may allow for sufficient conductive material to remain in contact with the upper S/D region 192 and lower S/D region 141, respectively, after the removal of the portion of the monolithic frontside contact 214 that is exposed by the contact cut opening 222. However, the substantially horizontal dimension 227 between the sidewall 223 and the sidewall 225 may be sufficiently large to adequately electrically isolate the conductive material that remains in contact with the upper S/D region 192 and lower S/D region 141, respectively, after the removal of the portion of the monolithic frontside contact 214 that is exposed by the contact cut opening 222.

The contact cut opening 222 may further include a front sidewall and a rear sidewall, in respective planes into and out of the page. The distance between the front sidewall and the rear sidewall may be larger than the similar distance of the monolithic frontside contact 214 so that after the removal of the portion of the monolithic frontside contact 214 that is exposed by the contact cut opening 222, the monolithic frontside contact 214 is separated into structurally different frontside contacts. In another example, the contact cut opening 222 may have a top view shape like a plus sign which may result in the monolithic frontside contact 214 being separated into, for example, four structurally different frontside contacts.

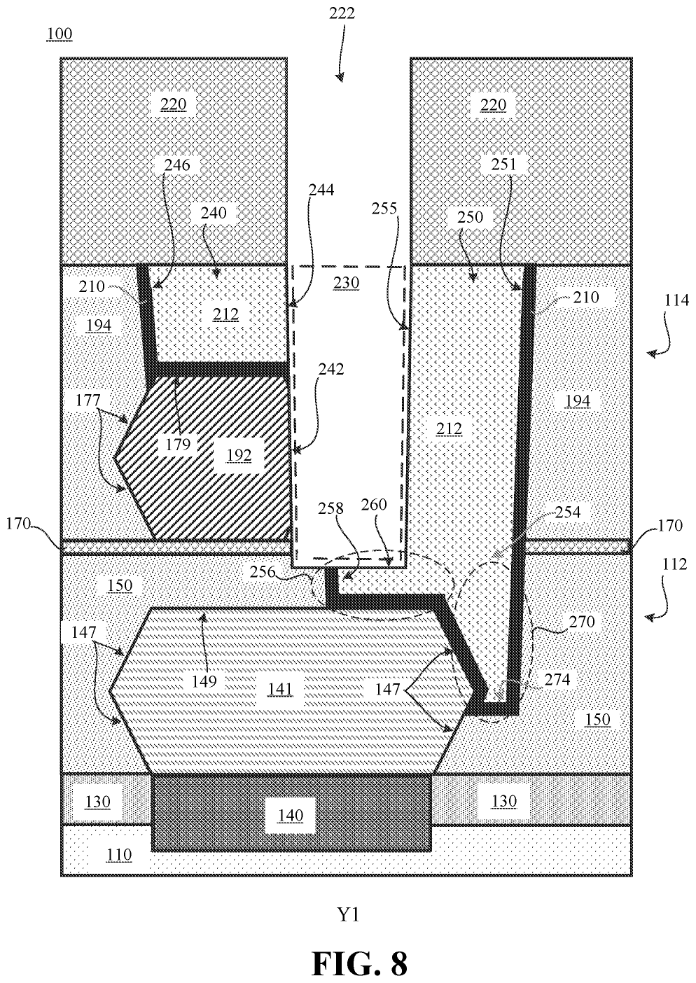

FIG. 8 depicts cross-sectional views of the semiconductor IC device 100 after fabrication operations, in accordance with embodiments of the present disclosure. In the depicted fabrication stage, contact cut region is formed within the monolithic frontside contact which resultantly splits the monolithic frontside contact into two or more frontside contacts. For example, contact cut region 230 is formed within the monolithic frontside contact 214, depicted in FIG. 7, which separates the monolithic frontside contact 214 into at least a first frontside contact 240 and a second frontside contact 250.

In the contact cut region 230 formation process, any suitable material removal process (e.g., reactive ion etching or RIE) may be used to remove the monolithic frontside contact 214 that is exposed by the contact cut opening 222 down to the level of below the bottom surface of the upper S/D region 192, or the like. For example, the bottom or well surface of the contact cut region may be between the bottom surface of the upper S/D region 192 and the (100) orientated crystallographic top surface 149 of the bottom S/D region 141. This may ensure that the second frontside contact 250 does not electrically connect with the upper S/D region 192. The material removal process to form the contact cut region 230 also effectively removes a portion of the upper S/D region 192 that is exposed by the contact cut opening 222. The remaining upper S/D region 192 therefore includes a S/D cut sidewall 242.

The contact cut region 230 may be formed by the suitable subtractive removal technique, such as an etch, that removes associated portion(s) of the monolithic frontside contact 214, conductive liner 210, upper S/D region 192, bonding layer 170, and lower ILD 150. The subtractive removal technique may be timed or otherwise controlled to stop such that the depth or bottom of the contact cut region 230 is between the upper S/D region 192 and the lower S/D region 141. Subsequently, the mask 220 may be removed by a subtractive removal technique, such as an etch, organic planarization layer (OPL) ash, or the like.

In an example, the first frontside contact 240 includes a first conductive portion 212 and an associated portion of conductive liner 210, which may be referred to herein as a first conductive liner 210. In an example, the first frontside contact 240 may be in direct contact with the upper S/D region 192. More particularly, the first conductive liner 210 may be in direct contact with the upper S/D region 192, the first conductive portion 212 may be indirectly connected to the upper S/D region 192, or the like. The first conductive portion 212 may include a first cut sidewall 244 that may be substantially coplanar with a S/D cut sidewall 242 of the upper S/D region 192.

In an example, the S/D cut sidewall 242 may be distal or otherwise opposing to the (111) crystallographic plane side surfaces 177 of the upper S/D region 192. The S/D cut sidewall 242 may be formed by removing one or more (111) crystallographic plane side surfaces of the upper S/D region 192 simultaneously with separating the monolithic frontside contact 214 into the first frontside contact 240 and the second frontside contact 250.

In an example, the second frontside contact 250 includes a second conductive portion 212 and an associated portion of conductive liner 210, which may be referred to herein as a second conductive liner 210. In an example, the second frontside contact 250 may be in direct contact with the lower S/D region 141. More particularly, the second conductive liner 210 may be in direct contact with the lower S/D region 141, the second conductive portion 212 may be indirectly connected to the lower S/D region 141, or the like. The second conductive portion 212 may include a second cut sidewall 255 that faces the S/D cut sidewall 242 and the first cut sidewall 244.

In an example, when a directional vertical etch is utilized to form contact cut region 230, the S/D cut sidewall 242, the first cut sidewall 244, and the second cut sidewall 255 are substantially vertical.

In an example, the first conductive portion 212 further includes a first opposing sidewall 246 that faces away from the second frontside contact 250, and the second conductive portion 212 further comprises a second opposing sidewall 251 that faces away from the first frontside contact 240.

In an example, formation of the contact cut region 230 also removes a portion of the conductive liner 210 and separates the conductive liner 210 into a first conductive liner 210 associated with the first frontside contact 240 and a second conductive liner 210 associated with the second frontside contact 250. The first conductive liner 210 may be between the first opposing sidewall 246 and the upper ILD 194 and between the first conductive portion 212 and the upper S/D region 192. That is, the first conductive liner 210 may exist on the surfaces of the first frontside contact 240 except for the S/D cut sidewall 244. In an example, the first conductive liner 210 may be between a bottom surface of the first conductive portion 212 and the (100) crystallographic plane top surface 179 of the upper S/D region 192.

In an example, the second conductive liner 210 is between the second opposing sidewall 251 and the upper ILD 194 and the lower ILD 150 and between the second conductive portion 212 and the lower S/D region 141. That is, the second conductive liner 210 may exist on the surfaces of the second frontside contact 250 except for the second cut sidewall 255 and a third cut sidewall 260. The third cut sidewall may be a part of the well or bottom surface of the contact cut region 230. In an example, the second conductive liner 210 may further be between a bottom surface 274 and a lower side surface 258 of the second conductive portion 212 and the bottom ILD 150.

In an example, the second conductive liner 210 may be directly against the (100) crystallographic plane top surface 149 of the lower S/D region 141. In an example, the second conductive liner 210 may be directly against the one or more (111) crystallographic plane side surfaces 147 of the lower S/D region 141. This may result due to the second frontside contact 250 including a wraparound portion 254 that includes at least a portion 256 that contacts against the (100) crystallographic plane top surface 149 and that includes at least a portion 270 that contacts against the one or more (111) crystallographic plane side surfaces 147 of the lower S/D region 141.

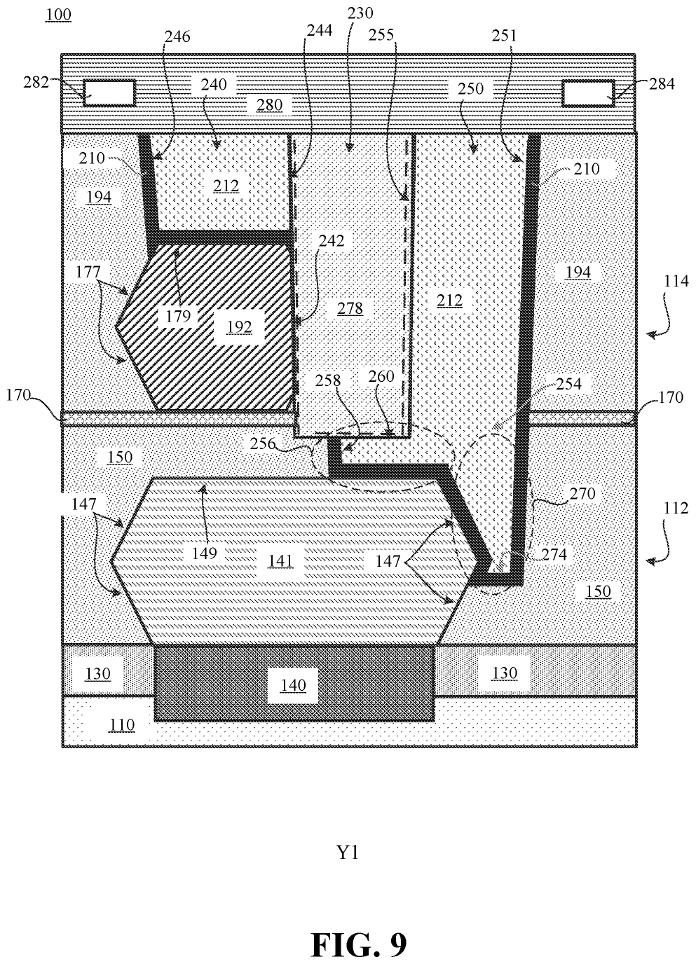

FIG. 9 depicts cross-sectional views of the semiconductor IC device 100 after fabrication operations, in accordance with embodiments of the present disclosure. In the depicted fabrication stage, an isolation region is formed within the contact cut region to adequately electrically isolate the two or more frontside contacts. For example, isolation region 278 is formed within the contact cut region 230 to adequately electrically isolate the first frontside contact 240 and the second frontside contact 250.

The isolation region 278 may be formed by depositing a blanket dielectric material deposited over the upper ILD 194, over the first frontside contact 240, over the second frontside contact 250, and within the contact cut region 230. The isolation region 278 can consist of any suitable material, such as, for example, porous silicates, oxides, silicon dioxides, silicon nitrides, silicon oxynitrides, or other dielectric materials. Any known manner of forming the isolation region 278 can be utilized. The isolation region 278 can be formed using, for example, CVD, PECVD, ALD, flowable CVD, spin-on dielectrics, or PVD.

In an example, the isolation region 278 may be formed to a thickness above the top surface of the first frontside contact 240 and the second frontside contact 250. Subsequently, a planarization process, such as a CMP, may be performed to remove excess lower isolation region 278 material. The planarization may also partially remove some of the first frontside contact 240 and the second frontside contact 250. The CMP may create a substantially planar or substantially horizontal top surface for the semiconductor IC device 100. In other words, the respective top surfaces of the upper ILD 194, first frontside contact 240, the second frontside contact 250, isolation region 278, and the like, may be substantially coplanar and/or substantially horizontal.

The isolation region 278 may be composed of but not limited to a low-κ material (e.g., an oxide material with a lower dielectric constant relative to SiO₂), or the like. In these examples, the low-κ material may better electrically isolate the first frontside contact 240 and the second frontside contact 250. This may allow for further device scaling since the horizontal distance between first cut sidewall 244 and the second cut sidewall 255 may be reduced while electrical isolation between the first frontside contact 240 and the second frontside contact 250 may be maintained. In this example, therefore, the material(s) that forms the isolation region 278 may be relatively different than the material(s) that form the lower ILD 150 and/or the upper ILD 194.

Alternatively, the isolation region 278 may be composed of but not limited to a high-κ dielectric material (e.g., a nitride material with a higher dielectric constant relative to SiO₂), or the like. In these examples, the high-κ material may better protect against diffusion of the material(s) of the first frontside contact 240 and the second frontside contact 250, which may prevent shorting therebetween. In this example, the horizontal distance between first cut sidewall 244 and the second cut sidewall 255 may be relatively greater than the previous example to ensure adequate electrical isolation between the first frontside contact 240 and the second frontside contact 250. Like the previous example, in this example, the material(s) that forms the isolation region 278 may be relatively different than the material(s) that form the lower ILD 150 and/or the upper ILD 194. In other examples, the isolation region 278 may be composed of the same material(s) as the lower ILD 150 and/or the upper ILD 194.

In an example, the third cut sidewall 260 may be between a bottom surface of the upper S/D region 192 and the (100) crystallographic plane top surface 149 of the lower S/D region 141. In an example, the isolation region 278 may be directly against the first cut sidewall 244, the second cut sidewall 255, the third cut sidewall 260, and the S/D cut sidewall 242. In other words, the conductive liner 210 is not present or otherwise between the first cut sidewall 244 and the isolation region 278, between the second cut sidewall 255 and the isolation region 278, between the third cut sidewall 260 and the isolation region 278, and between the S/D cut sidewall 242 and the isolation region 278.

In embodiments, the first frontside contact 240 and the second frontside contact 250 are formed as a part of middle-of-line (MOL) fabrication operations. In the semiconductor IC device fabrication industry, there are three sections referred to in a build: front-end-of-line (FEOL), back-end-of-line (BEOL), and the section that connects those two together, the MOL. The FEOL may be made up of the semiconductor devices, e.g., transistors, the BEOL may be made up of interconnects and wiring, and the MOL may be an interconnect between the FEOL and BEOL that includes material to prevent the diffusion of BEOL metals to FEOL devices.

BEOL may be the second portion of IC fabrication where the individual devices (e.g., transistors, capacitors, resistors, etc.) become interconnected with wiring on the wafer, e.g., the metallization layer or layers. BEOL includes contacts, insulating layers (dielectrics), metal levels, and bonding sites for chip-to-package connections. In the BEOL part of the fabrication stage contacts (pads), interconnect wires, vias and dielectric structures are formed. For modern IC processes, more than one metal layers may be added in the BEOL.

In the depicted example, a frontside BEOL network 280 may be formed over the frontside contact ILD, upon the first frontside contact 240, and upon the second frontside contact 250. Respective wires within the frontside BEOL network 280 may be electrically connected to the one or more S/D regions, one or more replacement gate structure(s), or the like, by a respective frontside contact(s). For example, a wire 282 wires within the frontside BEOL network 280 may be electrically connected to the upper S/D region 192 by the first frontside contact 240. Similarly, a wire 284 within the frontside BEOL network 280 may be electrically connected to the lower S/D region 141 by the second frontside contact 250.

The frontside BEOL network 280 may be located directly on the frontside surface of the MOL structures. The frontside BEOL network 280 can include one or more interconnect dielectric material layers (including one of the dielectric materials mentioned above for the upper ILD 194) and contains frontside metal wires (the metal wires can be composed of any electrically conductive metal or electrically conductive metal alloy) embedded therein. In some embodiments, the frontside metal wires within the frontside BEOL network 280 are composed of Cu. The frontside BEOL network 280 can include “x” numbers of frontside metal levels, wherein “x” may be an integer starting from 1. The frontside BEOL network 280 may further contain conductive pads that are connected to one or more of the metal wires and may be used to connect the semiconductor IC device to an external and/or higher-level structure, such as a chip carrier, motherboard, or the like.

For clarity, the semiconductor IC device 100 may continue with various fabrication operations to complete the fabrication thereof. For example, the semiconductor IC device 100 may undergo backside processing operations such as, removal of the substrate structure, removal of some backside contact placeholders 140, formation of backside contacts in place of the removed backside contact placeholders 140, formation of a backside BEOL network, and the like.

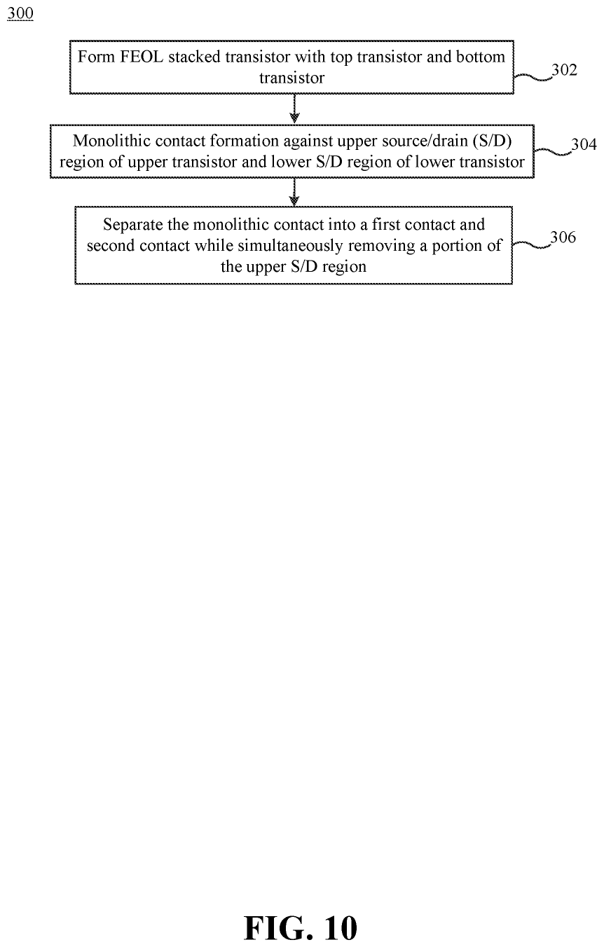

FIG. 10 depicts a flow diagram illustrating a method 300 to fabricate a semiconductor IC device, such as semiconductor IC device 100. The depicted fabrication operations of method 300 may be illustratively depicted and described above with reference to one or more of FIG. 3 through FIG. 9 of the drawings, which describe the fabrication of semiconductor IC device 100, though various fabrication operations described in method 300 may be used to fabricate other types of semiconductor IC devices. The method 300 depicted herein is illustrative. There can be many variations to the diagram or operations described therein without departing from the spirit of the embodiments. For instance, the operations can be performed in a differing order, or operations can be added, deleted, or modified.

At block 302, method 300 may begin with forming a stacked transistor that has a upper transistor and a lower transistor. The lower transistor includes at least one or more lower S/D region(s) and the upper transistor includes at least one or more upper S/D region(s). For clarity, block 302 may include finishing one or all FEOL fabrication operations associated with the formation of the stacked transistor.

At block 304, method 300 may continue with forming a monolithic frontside contact directly against both the upper transistor and the lower transistor. For example, monolithic frontside contact 214 is formed against both a lower S/D region 141 and an upper S/D region 192.

At block 306, method 300 may continue with separating the monolithic frontside contact into at least a first frontside contact and a second frontside contact while simultaneously (e.g., during the same subtractive removal stage, etch stage, or the like) removing a portion of the upper transistor. For example, a single etch sequence or stage separates the monolithic frontside contact 214 into the first frontside contact 240 and the second frontside contact 250 and also removes a portion of the upper S/D region 192.

For clarity, method 300 includes forming the monolithic frontside contact against the lower source/drain (S/D) region and against the upper S/D region and simultaneously separating the monolithic frontside contact into the first frontside contact and the second frontside contact and removing the portion of the upper S/D region.

Method 300 may also include, because of removing the portion of the upper S/D region, forming a first cut sidewall of the first frontside contact and forming a S/D cut sidewall of the upper S/D region that is coplanar with the first cut sidewall. For example, the first cut sidewall 244 of the first frontside contact 240 and the S/D cut sidewall 242 of the upper S/D region 192 may be coplanar.

For clarity, method 300 may include further fabrication stages associated with those fabrication stages described to fabricate the semiconductor IC device 100. For example, the simultaneously separation of the monolithic frontside contact and removal of the portion of the upper S/D region may effectively form contact cut opening 222 which may be filled by an isolation material to create contact cut region 230 that may separate the first frontside contact 240 and the second frontside contact 250 and separate the second frontside contact 250 from the upper S/D region 192. This separation may limit the propensity of the first frontside contact 240 from shorting with the second frontside contact 250, or vice versa. Similarly, this separation may limit the propensity of the second frontside contact 250 from shorting with the upper S/D region 192.

The descriptions of the various embodiments have been presented for purposes of illustration and are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments. the practical application or technical improvement over technologies found in the marketplace, or to enable others of ordinary skill in the art to understand the embodiments disclosed herein.

What is claimed is:

1. A semiconductor integrated circuit (IC) device comprising:
an upper transistor comprising an upper source/drain (S/D) region with a S/D cut sidewall;
a lower transistor comprising a lower S/D region;
a first frontside contact in contact with the upper S/D region, the first frontside contact comprising a first conductive portion with a first cut sidewall that is substantially coplanar with the S/D cut sidewall; and
a second frontside contact in contact with the lower S/D region, the second frontside contact comprising a second conductive portion with a second cut sidewall that faces the S/D cut sidewall and the first cut sidewall.

2. The semiconductor IC device of claim 1, wherein the S/D cut sidewall, the first cut sidewall, and the second cut sidewall are substantially vertical.

3. The semiconductor IC device of claim 1, further comprising:
an interlayer dielectric (ILD) directly against the S/D cut sidewall, the first cut sidewall, and the second cut sidewall.

4. The semiconductor IC device of claim 3, wherein the ILD is further directly against the upper S/D region, the lower S/D region, the first frontside contact, and the second frontside contact.

5. The semiconductor IC device of claim 4, wherein the first conductive portion further comprises a first opposing sidewall that faces away from the second frontside contact, and wherein the second conductive portion further comprises a second opposing sidewall that faces away from the first frontside contact.

6. The semiconductor IC device of claim 5, further comprising:
a first liner between the first opposing sidewall and the ILD and between the first conductive portion and the upper S/D region.

7. The semiconductor IC device of claim 6, further comprising:
a second liner between the second opposing sidewall and the ILD and between the second conductive portion and the lower S/D region.

8. The semiconductor IC device of claim 7, wherein the second liner is directly against a (100) crystallographic plane top surface of the lower S/D region.

9. The semiconductor IC device of claim 8, wherein the second liner is directly against one or more (111) crystallographic plane side surfaces of the lower S/D region.

10. The semiconductor IC device of claim 7, wherein the second conductive portion further comprises a third cut sidewall that is between a bottom surface of the upper S/D region and the (100) crystallographic plane top surface of the lower S/D region.

11. The semiconductor IC device of claim 10, wherein the ILD is further directly against the third cut sidewall.

12. A semiconductor integrated circuit (IC) device comprising:
an upper transistor and a lower transistor;
a first frontside contact comprising: a first conductive portion that has a first cut sidewall and that has a first opposing sidewall that faces away from the first cut sidewall, and a first liner between the first conductive portion and the upper transistor;
a second frontside contact comprising: a second conductive portion that has a second cut sidewall that faces the first cut sidewall and that has a second opposing sidewall that faces away from the second cut sidewall, and a second liner between the second conductive portion and the lower transistor; and
a contact cut region between the first frontside contact and the second frontside contact, the contact cut region comprising a first interlayer dielectric (ILD) directly upon the first cut sidewall and directly upon the second cut sidewall.

13. The semiconductor IC device of claim 12, wherein the first cut sidewall and the second cut sidewall are substantially vertical.

14. The semiconductor IC device of claim 13, further comprising:
a second ILD directly against the first liner and directly against the second liner.

15. The semiconductor IC device of claim 14, wherein the second ILD is composed of a different dielectric material relative to the first ILD.

16. The semiconductor IC device of claim 12, wherein the second liner is directly against a (100) crystallographic plane top surface of a lower S/D region of the lower transistor.

17. The semiconductor IC device of claim 16, wherein the second liner is further directly against one or more (111) crystallographic plane side surfaces of the lower S/D region.

18. The semiconductor IC device of claim 12, wherein the upper transistor comprises an upper source/drain (S/D) region with a S/D cut sidewall that is substantially coplanar with the first cut sidewall.

19. A method of fabricating a semiconductor integrated circuit (IC) device comprising:
forming a monolithic frontside contact against a lower source/drain (S/D) region and against an upper S/D region; and
simultaneously separating the monolithic frontside contact into a first frontside contact and a second frontside contact and removing a portion of the upper S/D region.

20. The method of claim 19, wherein simultaneously separating the monolithic frontside contact into the first frontside contact and the second frontside contact and removing the portion of the upper S/D region further comprises:
forming a first cut sidewall of the first frontside contact; and
forming a S/D cut sidewall of the upper S/D region that is coplanar with the first cut sidewall.
